(19) United States
(12) Patent Application Publication
(10) Pub. No.: US 2026/0073636 A1
(43) Pub. Date: Mar. 12, 2026

(54) PRODUCING A BLENDING FUNCTION MESH FOR INFERRING A BLENDING FUNCTION FOR A T-NURCCS SURFACE MODEL DEFINING A SMOOTH SURFACE

(71) Applicant: Autodesk, Inc., San Francisco, CA (US)

(72) Inventors: Adam Michael Helps, Provo, UT (US); Nicholas Stewart North, Vineyard, UT (US)

(21) Appl. No.: 19/322,637

(22) Filed: Sep. 8, 2025

Related U.S. Application Data
(60) Provisional application No. 63/692,616, filed on Sep. 9, 2024.

(51) Int. Cl. G06T 17/30; G06F 30/12; G06F 30/23; G06T 15/50; G06T 17/20

(52) U.S. Cl. CPC G06T 17/30; G06F 30/12; G06F 30/23; G06T 15/503; G06T 17/20; G06T 2200/24

(57) ABSTRACT

Methods, systems, and apparatus, including medium-encoded computer program products, for computer aided design of structures include, in one aspect, a method for inferring a blending function. A control mesh for a T-spline surface is obtained. A blending function mesh for inferring the blending function is generated for a control point of the T-spline surface by defining a topology for the blending function mesh. Defining the topology for the blending function mesh comprises: defining a central vertex and central edges of the blending function mesh that are inferred from the control mesh, and generating further topology for the blending function mesh by directly inferring further faces and edges for the blending function mesh from the defined central edges of the blending function mesh. The blending function for the T-spline surface can be inferred from the generated blending function mesh and provided providing for use for computing the T-spline surface.

### CROSS-REFERENCE TO RELATED APPLICATION

This application claims priority to U.S. Provisional Application No. 63/692,616 filed on Sep. 9, 2024. The disclosures of the prior applications are considered part of and is incorporated by reference in the disclosure of this application.

### BACKGROUND

### Technical Field

This specification relates to surface modelling in computer graphics applications, such as computer-generated animation and/or computer aided design of physical structures to be manufactured using additive manufacturing, subtractive manufacturing and/or other manufacturing systems and techniques.

### Description of Related Art

Computer graphics applications include different software products and/or services that support generation of representations of three-dimensional (3D) objects that can be used for manufacturing of physical structures corresponding to the objects, for visualization of scenes on display devices, for animation and video rendering, etc. Computer Aided Design (CAD) software has been developed and used to generate 3D representations of objects, and Computer Aided Manufacturing (CAM) software has been developed and used to manufacture the physical structures of those objects, e.g., using Computer Numerical Control (CNC) manufacturing techniques. Computer Aided Industrial Design (CAID) programs are a subset of CAD software programs that support generation of representations of 3D objects with a focus on technical aspects of the design methodology for presenting organic shapes and complex curves. Computer-Aided Engineering (CAE) software supports engineering analysis tasks and enables users to perform simulation, validation, evaluation, and optimization tasks related to manufacturing physical entities using CNC manufacturing techniques.

Typically, CAD software can create organic shapes by storing the 3D representations of geometry of objects by using surface models including B-Spline surfaces, Non-Uniform Rational Basis Splines (NURBS), Non-Uniform Catmull-Clark (NURCCS) surfaces, Catmull-Clark subdivision surfaces, T-Splines, T-NURCCs (Non-uniform Rational Catmull-Clark Surfaces with T-junctions) surfaces (as a superset of both T-splines and Catmull-Clark surfaces), among other example models.

The control points for a B-spline Surface are required to be topologically arranged in a rectangular grid. B-spline Surfaces are comprised of several parametric Surface patches that can be represented in Bézier form. A non-uniform rational B-Spline surface is referred to as a NURBS surface. A NURBS surface is a geometric representation of a smooth surface where the NURBS surface is described by its degree, weighted control vertices, and knot vector. NURBS is a smooth surface modelling representation commonly used in 3D computer graphics applications (e.g., CAD, CAM, and CAE products) as the typical representation of curves and curved surfaces, and are part of various industry wide standards. A NURBS surface is a geometric representation of a smooth surface where the NURBS surface is described by its degree, weighted control vertices, and knot vector. NURBS surfaces are a generalization of Bézier surfaces.

T-splines are a generalization of NURBS that do not require a complete grid of control points. T-spline control mesh permit T-junctions, so lines of control points need not traverse the entire control mesh. As such, T-junctions allow T-splines to be locally refinable: control points can be inserted into the control mesh without propagating an entire row or column of control points. T-splines support many valuable operations within a consistent framework, such as local refinement and merging of several B-spline surfaces that have different knot vectors into a single gap-free model.

T-NURCCs enable true local refinement of a Catmull-Clark-type control mesh by allowing individual control points to be inserted only where they are needed to provide additional control, or to create a smoother tessellation, and such insertions do not alter the limit surface. T-NURCCs use stationary refinement rules and are C2 continuous except at extraordinary points. T-splines and T-NURCCS surfaces can be used for the creation of organic shapes in CAD programs.

An extraordinary point is (1) a vertex on the control mesh where n control polygon faces meet, in the mesh interior, and n is not equal to four, and also (2) a vertex on the control mesh where n control polygon faces meet, at the mesh boundary, and n is greater than three. An extraordinary point may be associated with a “star point.” The “star point” can be defined as a corresponding point on the limit surface where (1) n surface patches meet, in the surface interior, and n is not equal to four, and/or (2) n surface patches meet, at the surface boundary, and n is greater than two. Further, an “N-gon” refers to a face of a control polygon of the subdivision surface control mesh with N corner vertices of the mesh with N not being equal to four. Both extraordinary points and N-gons in the control mesh leads to star points on the limit surface. For the purpose of defining N-gons, a T-junction on a side of a face is not considered a corner vertex. For example, a face with five vertices where one of those vertices is a T-junction on the side of that face is not considered an N-gon.

Both T-NURCCS and T-Splines allow T-junctions. Traditionally, T-splines do not allow extraordinary points on the surface, whereas T-NURCCS are a generalization of T-Splines that does allow extraordinary points on the surface. Further, T-junctions allow T-splines and T-NURCCS to be locally refinable since control points can be inserted into the control grid without propagating an entire row or column of control points, which supports efficient local control over the shape of the surface. On the other hand, surfaces like Catmull-Clark subdivision surfaces and NURBS surfaces often require the addition of many superfluous control points or complex topology to add local control.

Refinement of a NURBS control mesh is accomplished through a procedure called knot insertion whereby one or more new knot values are inserted into a knot vector. Knot insertion does not alter the surface, but it provides more control points with which the designer can manipulate the model. Because NURBS control points must lie topologically in a rectangular mesh, knot insertion causes one or more entire rows of control points to be added to the control mesh.

Computer graphics applications also include computer animation programs and video production applications that generated 3D representations of objects in motion. Computer graphics software applications can be used in conjunction with subtractive manufacturing systems and techniques, such as CNC machine cutting, electrode discharge machining, chemical machining, and waterjet machining, to generate physical entities from the designed 3D models. For example, CAD software has been used in conjunction with additive manufacturing systems and techniques, also known as solid free form fabrication or 3D printing, such as Fused Filament Fabrication (FFF) and Selective Laser Sintering (SLS). In addition, CAD software has been designed so as to perform automatic generation of 3D geometry (generative design) for a part or one or more parts in a larger system of parts to be manufactured. The output from generative design algorithms is typically a discretized polygon mesh, similar to the output from object scanning systems and techniques. To be useable in a computer graphics application, such polygon meshes are typically converted into modelled surfaces composed of a control mesh and control vertices that define smooth surface patches of the complex modelled surface, e.g., a polygon mesh is converted into a complex T-Spline surface model.

### SUMMARY

This specification relates to surface modelling in computer graphics applications, such as computer-generated animation and computer aided design of physical structures to be manufactured using additive manufacturing, subtractive manufacturing, and/or other manufacturing systems and techniques. Surfaces of modeled objects can be represented using different surface models where surfaces can be defined in terms of blending functions. The blending functions can describe how control points of their respective control meshes influence points on the limit surface.

T-spline surfaces, among other surfaces, can be described in terms of blending functions. T-spline surfaces are characterized by the fact that they provide T-junctions. In view of the present disclosure, as used herein, “T-Spline” or “T-spline” does not refer to traditional T-Splines that do not allow extraordinary points, but rather to T-Splines that have been modified to allow extraordinary points, and the described systems and techniques are usable with T-NURCCS, which also use T-junctions. T-junctions provide efficient local control over the shape of the surface. A T-spline surface is not well-defined when an extraordinary point of the control mesh is “engulfed”. An extraordinary point is “engulfed” when the control mesh of the T-spline includes a control point whose blending function should include an extraordinary point (according to the T-Spline blending function inference rules), but where the subdivision face-counting rules cannot produce a valid blending function. As extraordinary points are common in practice, there is a need for defining T-spline surfaces including a T-junction and an extraordinary point in close proximity.

Available inference algorithms support inference of blending function in cases where the blending function is generated for a region that is associated with the presence of either a T-junction(s) or an extraordinary point(s). When a blending function is inferred for a T-spline surface that includes an extraordinary point and a T-junction in a control mesh of the surface, available inference algorithms for the T-spline surface blending function do not support inference of a blending function without affecting the quality of the resulting limit surface. For example, available algorithms for defining the surface of a T-Spline or T-NURCCS require that the surface is divided into zones that each support either T-junctions or

Such inefficiency and limitations related to the use and representation of a T-spline that includes both an extraordinary point and a T-junction that are within a certain distance can be overcome by introducing a generalized mechanism for inferring a blending function that can support such T-splines. In some implementations, a generalized mechanism for inferring of a blending function of such a T-spline can be defined to include a generation of a blending function mesh that can be used to infer a blending function for a T-spline surface having an engulfed extraordinary point. Such an inference mechanism may involve modification of the control mesh of the T-spline. For example, the blending function mesh can be generated without additional topology being added within the control mesh to add faces between the T-junction and the extraordinary point to artificially modify the control mesh so that there is sufficient distance between the T-junction and the extraordinary point.

In some implementations, the blending function mesh can be generated by defining a central vertex and central edges of the blending function mesh that are inferred from the control mesh, and further topology can be generated by directly inferring further faces and edges for the blending function mesh from the defined central edges of the blending function mesh.

Particular embodiments of the subject matter described in this specification can be implemented to realize one or more of the following advantages. By using a robust method for inferring a blending function from a generated blending function mesh that allows a control mesh to include any arrangement of T-junctions near extraordinary points, T-spline surfaces including a T-junction and an extraordinary point in close proximity can be represented efficiently while maintaining surface quality. Such a method has much less stringent requirements for the surface topology compared to available methods that require modification of the surface topology. Based on implementations of the present subject matter, users are supported to generate new topologies that produce higher quality surfaces with fewer constraints.

In accordance with implementations of the present disclosure, a blending function mesh as generated has a topology that accurately represents the parameter space of the T-spline surface. The blending function mesh (as generated according to the present disclose) can be used to infer the blending function that is backwards compatible with face counting and T-spline inference algorithms. Such techniques can simplify T-Spline modeling when users define surfaces using T-points and can support improved quality of the surfaces without the need to provide complex rules to the users to instruct them how to avoid constraints or to achieve better quality. These techniques are associated with performance improvements including reducing the need to cache blending function information for surfaces since recomputing of an area of a surface that is changed can be done for the area itself without a re-computation of the whole surface model. This will reduce the memory footprint and resource expenditures.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIG. 1 shows an example of a system usable to generate a smooth surface for output from a blending function that is inferred from a blending function mesh that is produced by generating topology inferred from the T-spline surface and the blending function mesh itself.

FIG. 2A shows an example control polygonal control mesh that is a three-dimensional mesh with control vertices, which define a smooth surface representing a portion of an object.

FIG. 2B shows an example of a polygonal mesh that includes a T-junction.

FIG. 3A shows an example of a process that produces a T-spline surface from a control mesh by generating a blending function mesh in accordance with implementations of the present disclosure.

FIG. 3B shows an example of a process that generates a blending function mesh for inferring a blending function to computer a T-spline surface in accordance with implementations of the present disclosure.

FIGS. 4A-4D, 5A-5E, and 6A-6D represent steps for generate a blending function mesh based on an example of a control mesh.

FIG. 7A shows an example of a resultant blending function mesh.

FIG. 7B shows an example of a blending function mesh.

FIG. 8 shows a blending function mesh generated based on a control mesh, where

the control mesh includes N-gons.

FIG. 9 shows a control mesh for an object including a vertex determined to require a welding adjustment due to welding of some of the vertices and edges of the control mesh.

FIG. 10 shows a control mesh that engulfs a hole.

FIG. 11 shows a control mesh that is associated with detection of engulfment when generating the blending function mesh.

FIG. 12 shows generating a blending function mesh based on a control mesh having an axial edge touching a center of an N-gon in the control mesh.

FIG. 13 is a schematic diagram of a data processing system including a data processing apparatus, which can be programmed as a client or as a server.

Like reference numbers and designations in the various drawings indicate like elements.

### DETAILED DESCRIPTION

The present disclosure describes various tools and techniques for generating smooth surfaces for output by a computer graphics application. The smooth surfaces can be generated based on inferring a blending function for a control point on the surface by defining a topology for a blending function mesh based on an obtained control mesh for a T-spline surface.

A blending function can represent the points on the limit surface as a weighted average of control points of a control mesh defined for the limit surface. The blending functions for respective control points can provide the weights for the control points to represent how the control points affect the surface shape. As such, the blending function can be interpreted to define how each control point on a control mesh affects the surface shape.

For example, the blending function can be used to determine how moving a particular control point changes the surface shape around any point on a T-spline surface. The blending function of the central vertex of the control mesh can be multiplied by a vector of the movement to determine how at least a portion of the T-spline surface will change. Thus, modifications of the control mesh to support inferring a blending function with existing inference algorithms can result in reduced quality of the resulting limit surface produced through such combined algorithms and can be inefficient.

Since T-splines are non-uniform B-spline surfaces where the T-spline control meshes permit T-junctions, the lines of control points need not traverse the entire control mesh in contrast to NURBS. In other words, T-junctions allow T-splines to be locally refinable and control points can be inserted into the control mesh without propagating an entire row or column of control points. However, T-junctions in T-splines are not well-defined when they fall within the two-ring of faces around an extraordinary point in the control mesh, i.e., when an extraordinary point is within two neighborhoods of faces extending from the extraordinary point, and a T-junction is provided within those two neighborhoods of faces. As extraordinary points can often occur in practice, complexity in representation of T-junctions near extraordinary points may limit the utility of T-junctions in T-Splines.

In some cases, since a NURBS surface does not include star points, T-splines can be described using a classic NURBS blending function only in cases where a T-junction does not appear near an extraordinary point. While T-junctions can be defined in terms of the NURBS blending function they produce, the NURBS blending function does not allow extraordinary points (corresponding to the star point on the smooth surface). Thus, areas of a surface where T-junctions are well defined can be called “NURBS-like regions”, while areas close to an extraordinary point where T-junctions are forbidden can be called “subdivision-like regions”. In the NURBS-like regions of the surface, each control point's effect on the surface can be determined by its associated basis function (blending function).

In some instances, if a T-Spline includes T-junctions and extraordinary points (and in some cases those are relatively close, e.g., where a T-junction is within the two-ring of faces around an extraordinary point), modification of the topology of the control mesh in order to define the limit surface can be performed on the control mesh of the T-Spline so that all extraordinary points on the control mesh are away from T-junctions (outside of the two-ring of faces around the extraordinary point). However, such refinement can be associated with the use of a lot of computation resources to generate the refined mesh and can be associated with reducing the precision of the final surface that can be computed. In some cases, such refinement can result in additional control points being added to the control mesh to separate the T-junction from the extraordinary point, and regions around T-junctions and around extraordinary points can be treated differently and different blending functions can be used for the different regions. To determine the surface shape in regions around an extraordinary point (for example, in a subdivision-like region), local non-uniform subdivision rules can be applied to that region, and NURBS basis function can be used in a region(s) allowing T-junction(s) (for example, in NURBS-like regions).

Such an approach of performing “repairs” (modification or addition of topology) to the control mesh in order to introduce additional topology in the control mesh to provide a “distance” (e.g., as needed to overcome the constraints of an available blending function) between T-junctions and extraordinary points can be costly and time consuming. Additionally, this approach can result in a reduced surface quality. To address these issues, a generalized mechanism for inferring a blending function for a control point of a T-spline surface can be provided that is agnostic to the topology of the control mesh and can support T-splines including an extraordinary point and a T-junction in close proximity, for example, when the T-junction falls within a two-ring of faces around the extraordinary point.

In some implementations, inferring the blending function of such a T-spline can be defined to include a generation of a blending function mesh that can be used to infer a blending function for a T-spline surface having such an engulfed extraordinary point. The inference of the blending function can be performed without modifying the control mesh for the T-spline but rather by generating a topology for the blending function mesh by directly inferring faces and edges for the blending function mesh from a defined central vertex and central edges of the blending function mesh that were directly inferred from the control mesh.

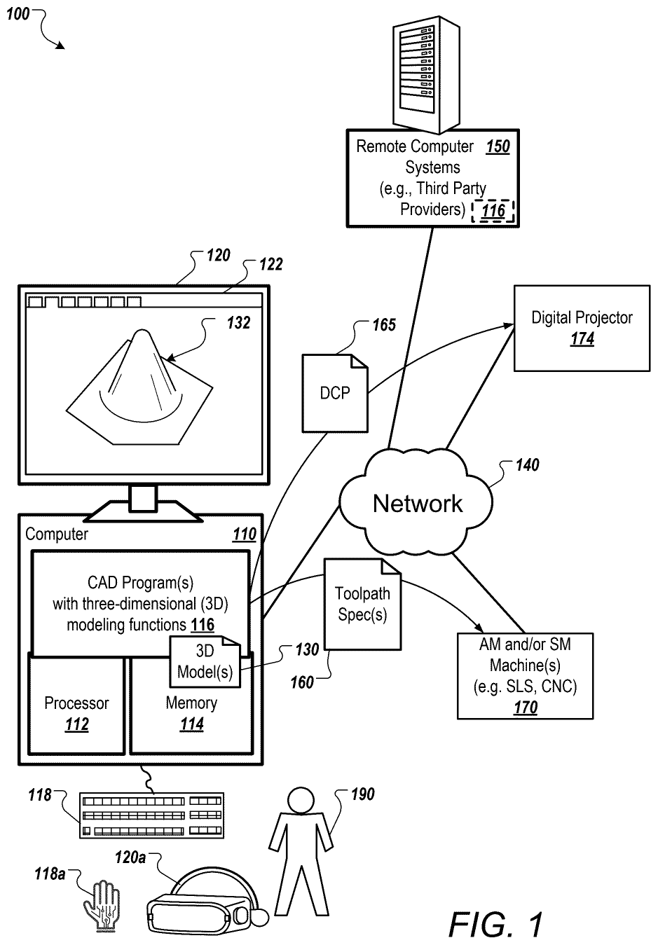

FIG. 1 shows an example of a system 100 usable to generate a smooth surface for output based on a blending function inferred from a blending function mesh generated from a control mesh in accordance with implementations of the present disclosure. A computer 110 includes a processor 112 and a memory 114, and the computer 110 can be connected to a network 140, which can be a private network, a public network, a virtual private network, etc. The processor 112 can be one or more hardware processors, which can each include multiple processor cores. The memory 114 can include both volatile and non-volatile memory, such as Random Access Memory (RAM) and Flash RAM. The computer 110 can include various types of computer storage media and devices, which can include the memory 114, to store instructions of programs that run on the processor 112, including CAD program(s) 116, which implement three-dimensional (3D) modeling functions.

As used herein, CAD refers to any suitable program used to design physical structures that meet specified design requirements, regardless of whether or not the program is capable of interfacing with and/or controlling specific manufacturing equipment. Thus, CAD program(s) 116 can include CAID program(s), CAE program(s), CAM program(s), etc. The program(s) 116 can run locally on computer 110, remotely on a computer of one or more remote computer systems 150 (e.g., one or more third party providers' one or more server systems accessible by the computer 110 via the network 140) or both locally and remotely. Thus, a CAD program 116 can be two or more programs that operate cooperatively on two or more separate computer processors in that a program 116 operating locally at computer 110 can offload processing operations (e.g., subdivision surface, NURBS and NURCCS processing, adjustments to subdivision operations, etc.) “to the cloud” by having one or more programs 116 on one or more computers 150 perform the offloaded processing operations.

The CAD program(s) 116 present a user interface (UI) 122 on a display device 120 of the computer 110, which can be operated using one or more input devices 118 of the computer 110 (e.g., keyboard and mouse). Note that while shown as separate devices in FIG. 1, the display device 120 and/or input devices 118 can also be integrated with each other and/or with the computer 110, such as in a tablet computer (e.g., a touch screen can be an input/output device 118, 120). Moreover, the computer 110 can include or be part of a virtual reality (VR) or augmented reality (AR) system. For example, the input/output devices 118, 120 can include a VR/AR input glove 118a (or other hand manipulating tools or VR/AR input controllers generally) and/or a VR/AR headset 120a.

As noted above, the CAD program(s) 116 implement 3D modeling functions, which means a 3D model 132 can be built using the CAD program(s) 116. The CAD program(s) 116 can implement physical simulation (locally and/or by remote procedure call) to assist in building the 3D model 132. Physical simulations, such as finite element analysis (FEA), Computational Fluid Dynamics (CFD), Acoustics/Noise Control, thermal conduction, and/or computational injection molding simulations are often integral components in CAD-based product development. The CAD program(s) 116 can be used to build precise geometric descriptions of the design model, while physical simulations enable improved performance without time consuming physical testing.

A user 190 can interact with the UI 122 of the CAD program(s) 116, including producing a full mechanical problem definition for a part to be manufactured, so as to build and modify 3D model(s) 132, which can be stored in 3D model document(s) 130. In the example of FIG. 1, the 3D model 132 is of a specific design of an object or part of an object, and this is merely one of many possible 3D models that can be designed using the systems and techniques described herein.

In the example shown, the 3D model 132 rendered to the display device 120 in the UI 122 is a complex T-Spline surface model that is the output result from a blending function inference process based on generating a blending function mesh in accordance with the present disclosure. A control mesh for a T-spline surface is called a T-mesh. In some instances, the control mesh can include an extraordinary point and a T-junction that falls within a two-ring of faces around the extraordinary point.

Generally, the T-Spline surface can be computed based on blending functions for control points of the surface. When a T-spline function is described in terms of blending functions, a unified blending function can be used for the representation that is defined piecewise using a blending function mesh. A blending function can be inferred from the blending function mesh, and the blending function mesh can be generated by defining a topology inferred from the control mesh in accordance with implementations of the present disclosure.

In some implementations, computer graphic applications (e.g., CAD program(s) 116) can represent objects (e.g., manufacturable objects) though models of complex surfaces. Such models include for example, NURCCS surfaces, NURBS surfaces, T-splines, or other. The models of complex surfaces can be presented as polygonal control meshes that are an approximation of a continuous representation of the manufacturable objects. Such models can be defined with meshes that have different levels of refinement. In some implementations, a model may have some region where the mesh is finer and some other region where the mesh is coarser.

In addition, in some implementations, the CAD program(s) 116 implement manufacturing control functions. Once the user 190 is satisfied with a 3D model 132, the 3D model 132 can be stored as the 3D model document(s) 130 and/or used to generate another representation of the model (e.g., an .STL file for additive manufacturing). This can be done upon request by the user 190, or in light of the user's request for another action, such as sending the 3D model 132 to additive manufacturing (AM) machine(s) and/or subtractive manufacturing (SM) machine(s) 170, or other manufacturing machinery, which can be directly connected to the computer 110, or connected via a network 140, as shown. This can involve a post-process carried out on the local computer 110 or a cloud service to export the 3D model 132 to an electronic document from which to manufacture. Note that an electronic document (which for brevity will simply be referred to as a document) can be a file, but does not necessarily correspond to a file. A document may be stored in a portion of a file that holds other documents, in a single file dedicated to the document in question, or in multiple coordinated files.

In any case, the CAD program(s) 116 can provide a document 160 (having toolpath specifications of an appropriate format) to an AM and/or SM machine 170 for use in manufacturing the physical structure using various cutting tools, etc., where the physical structure corresponds to at least a portion of the 3D model 132. An AM machine 170 can employ one or more additive manufacturing techniques, such as granular techniques (e.g., Powder Bed Fusion (PBF), Selective Laser Sintering (SLS) and Direct Metal Laser Sintering (DMLS)), extrusion techniques (e.g., Fused Deposition Modelling (FDM), which can include metals deposition AM). In some cases, the AM machine 170 builds the physical structure directly, and in some cases, the AM machine 170 builds a mold for use in casting or forging the physical structure. In addition, the user 190 can save or transmit the 3D model 132 for later use. For example, the CAD program(s) 116 can store the document(s) 130 that includes the 3D model 132.

An SM machine 170 can be a Computer Numerical Control (CNC) milling machine, such as a multi-axis, multi-tool milling machine used in the manufacturing process. For example, the CAD program(s) 116 can generate CNC instructions for a machine tool system 170 that includes multiple tools (e.g., solid carbide round tools of different sizes and shapes, and insert tools of different sizes that receive metal inserts to create different cutting surfaces) useable for various machining operations.

In some implementations, the CAD program(s) 116 can include suitable algorithms to generate toolpath specifications 160 for one or more of these various systems to manufacture a part that has been designed using the systems and techniques described in this application. In addition, in some implementation, no physical manufacturing is involved. The systems and techniques described herein are applicable to any suitable surface modelling software. Thus, in some implementations, the CAD program(s) 116 can be animation production programs that render the 3D model 132 to a document 165 of an appropriate format for visual display, such as by a digital projector 174 (e.g., a digital cinema package (DCP) 165 for movie distribution) or other high resolution display device. In some other examples, the CAD programs(s) 116 can be video production software that render the 3D model 132 and/or other models generated by the CAD program(s) 116 as part of a rendered scene or frame. Other applications are also possible.

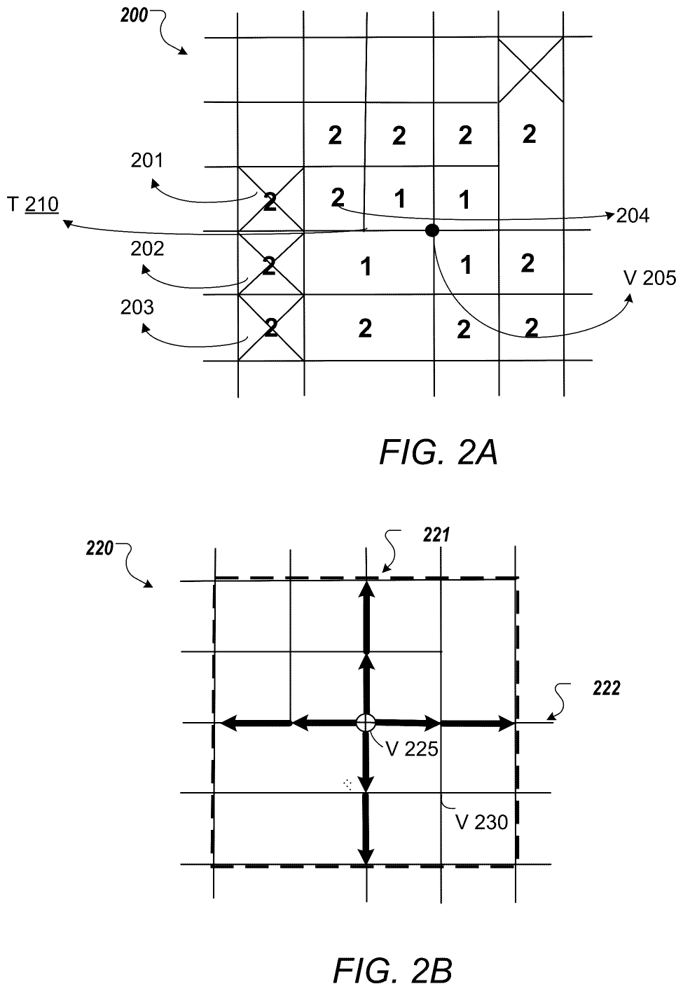

FIG. 2A shows an example control polygonal control mesh 200 that is a three-dimensional mesh with control vertices, which define a smooth surface representing a portion of an object. The polygonal control mesh 200 defines a smooth surface and can be stored as a T-Spline surface. For example, the polygonal control mesh 200 can be related to a portion of the surface of the 3D model 132 presented on UI 122 in FIG. 1. The polygonal control mesh 200 includes a vertex V 205 with a valence number equal to four (i.e., four (4) edges going out of the vertex). The polygonal control mesh 200 also includes a vertex T 210 that is a T-junction.

Surfaces, including T-spline surfaces, can be described in terms of blending functions for the control points of the control mesh. In some instances, T-spline surfaces can be described using a NURBS blending function, where T-points can be defined in terms of the NURBS blending function they produce. However, NURBS blending functions cannot be used to represent extraordinary points. These NURBS blending functions are not capable of representing extraordinary points because a rectangular parametrization is an inherent part of the formulation. T-NURCCS surfaces require that T-junctions are only used in NURBS-like regions of the surface when a NURBS blending function is to be used for the T-spline surface.

NURBS basis blending functions can be represented with a bivariate equation that is non-zero over a parametrically rectangular region. These NURBS blending functions are not capable of representing extraordinary points because the rectangular parametrization is an inherent part of the formulation.

In some cases, subdivisions can be applied in the area around the extraordinary point to provide additional control points in the mesh. With each subdivision step, the size of the blending function for the extraordinary point can be decreased, which may allow use of the NURBS blending function closer and closer to the extraordinary point. However, applying subdivisions cannot be used to separate existing T-junctions from extraordinary points since the subdivision rules are not well defined in the presence of T-junctions.

In some instances, if a surface includes T-junctions and extraordinary points that are close to one another, the surface can be divided into two zones, where a first zone that is close to an extraordinary point where T-junctions are forbidden (a.k.a., a subdivision-like region) and a second zone—where T-junctions are allowed but no extraordinary points are present (a.k.a., a NURBS-like region). In the NURBS-like regions of the surface, each control point's effect on the surface can be determined by its associated NURBS basis function. A different function can be used to define how control points affect the surface in the “subdivision-like regions”, however, generating a blending function based on a mixture of the two types of blending functions still does not allow the presence of a T-junction within two-rings of extraordinary points.

On a subdivision surface (where T-junctions are not allowed), a blending function can be represented using a small subdivision mesh (a “blending function mesh”) that includes some subset of the faces from the original mesh. Coefficients can be assigned to the vertices, and those coefficients can be interpolated instead of interpolating the control points that are three-dimensional points. The central vertex on the blending function mesh is assigned a coefficient of “1” and all others are assigned a coefficient of “0.” Subdivision is then performed, but instead of interpolating 3D points, the coefficients are interpolated. The limit surface after subdividing this blending function mesh is the blending function for the central vertex. For a cubic Catmull-Clark surface, it includes the vertex-connected two-ring of faces around the central vertex. The faces around the central vertex can be assigned with “1” as they include a vertex that is the central vertex, and the faces around the first ring can be assigned with “2”, so that a face counting rule can be applied for the subdivision surfaces, starting from the central vertex. For the Catmull-Clark surface, the blending function includes two rings of faces, where the first ring is assigned with count number “1” and the second ring is assigned with count number “2”. This is referred to this as the “face counting rule.”

While NURBS basis functions cannot represent extraordinary points, subdivision blending functions can represent extraordinary points. Subdivisional blending functions are equivalent to uniform B-splines when they do not include extraordinary point(s). The subdivision blending functions can be extended to be compatible with non-uniform B splines that include extraordinary points by applying knot intervals to each edge and applying a subdivision scheme to incorporate these knot intervals.

A non-uniform blending function mesh can be used to represent uniform and non-uniform subdivision surfaces. Non-uniform subdivision surfaces are a superset of both Catmull-Clark surfaces and NURBS surfaces, however, a non-uniform blending function mesh can be used to generalize a topology that includes T-junctions in accordance with implementations of the present invention.

In the example of the control mesh 200, which is of a T-spline and includes the T-junction 210, only NURBS blending functions can be used to represent the whole surface. However, in that case, because of the T-junction being present in the topology, as shown in FIG. 2A, subdivision blending functions would not be applicable. As shown in FIG. 2A, trying to apply the face counting rules to define level neighbor faces to faces may not be possible. If such face counting rules are to be applied as shown in FIG. 2A, the faces around the vertex point are assigned with first level neighbor face count, and faces around those first level neighbor faces are assigned with second level neighbor count. However, based on such face counting, there will be faces such as face 201, 202, or 203 that will be assigned a face count of two (2), but these faces should not be included in the blending function according to the T-spline blending function inference rules.

FIG. 2B shows an example of a polygonal mesh 220 that includes a T-junction. The polygonal mesh 220 includes a portion of the polygonal mesh 200, where the vertex 225 corresponds to the vertex V 205 of FIG. 2A. In some instances, the polygonal mesh 220 can be a portion of a larger polygonal mesh that includes extraordinary points. While there are different algorithms for inferring a blending function, those may not be applicable in cases where both a T-junction and an extraordinary point are part of the polygonal mesh.

For example, NURBS blending functions are not capable of representing extraordinary points. On subdivision surfaces, a blending function can be represented using a subdivision mesh that includes a subset of the faces of the original polygonal mesh. It is possible to extend subdivision surfaces to be fully compatible with non-uniform B-splines by adding a knot interval to each edge and using a subdivision scheme to incorporate these knot intervals. Non-uniform subdivision surfaces are a superset of the NURBS surfaces, and thus, such non-uniform blending function meshes can be used to represent blending functions in NURBS-like regions and in subdivision-like regions. However, a face counting rule may not be available for topologies that include a T-junction. For example, as shown on FIG. 2A, the T-junction T 210 implies the inclusion of faces or portions of faces (showed as crossed out on FIG. 2A) that will not properly belong to the blending function.

In some instances, to infer a blending function based on the polygonal control mesh 220, the axes of influence of the blending function can be determined. Axes 221 and 222 can be determined and they cross at the central vertex V 225. The axes on the control mesh 220 can be used to provide the dimensions and continuity breaks of a rectangular blending function. Relying on face counting rules may not be applicable to infer the blending function in all cases. If there is an extraordinary point either along the axes where a T-junction is present, neither T-spline blending function inference algorithms nor face counting algorithms will be applicable. For example, neither of those algorithms will be applicable if vertex V 230 was an extraordinary point where not four, but five vertices are meeting (not shown on FIG. 2B) since such an extraordinary point would be engulfed by the blending function (that has a rectangular domain).

In accordance with the present disclosure, an inference algorithm is provided to infer a blending function from a polygonal mesh that may or may not have T-junctions and extraordinary points. Such an algorithm will allow inference of a blending function when both T-junctions and extraordinary points are present in the control mesh. The provided approach is backward compatible with the face counting rule and the T-spline inference algorithm, and can be considered as a uniform approach that may be agnostic to the presence and/or exact location of T-junctions and extraordinary points in the control mesh.

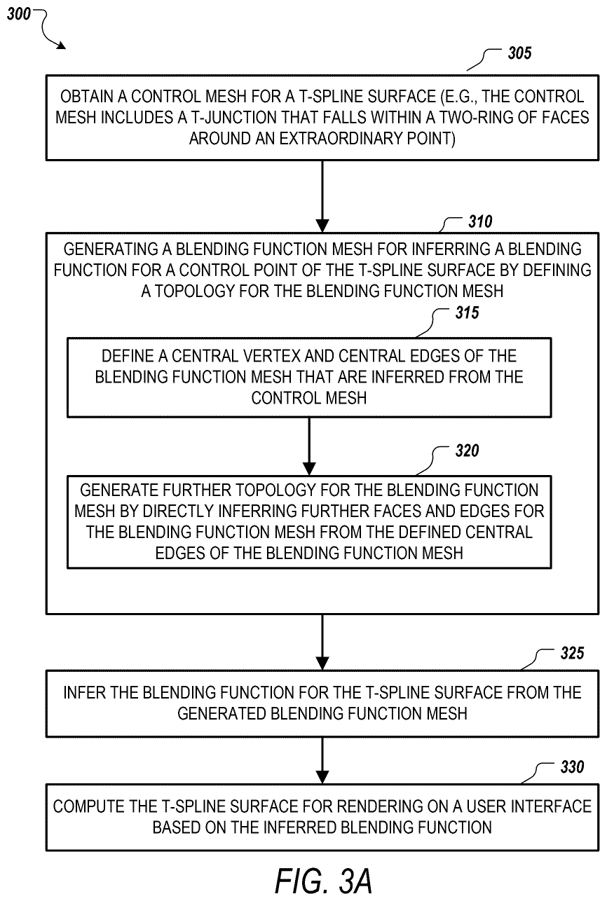

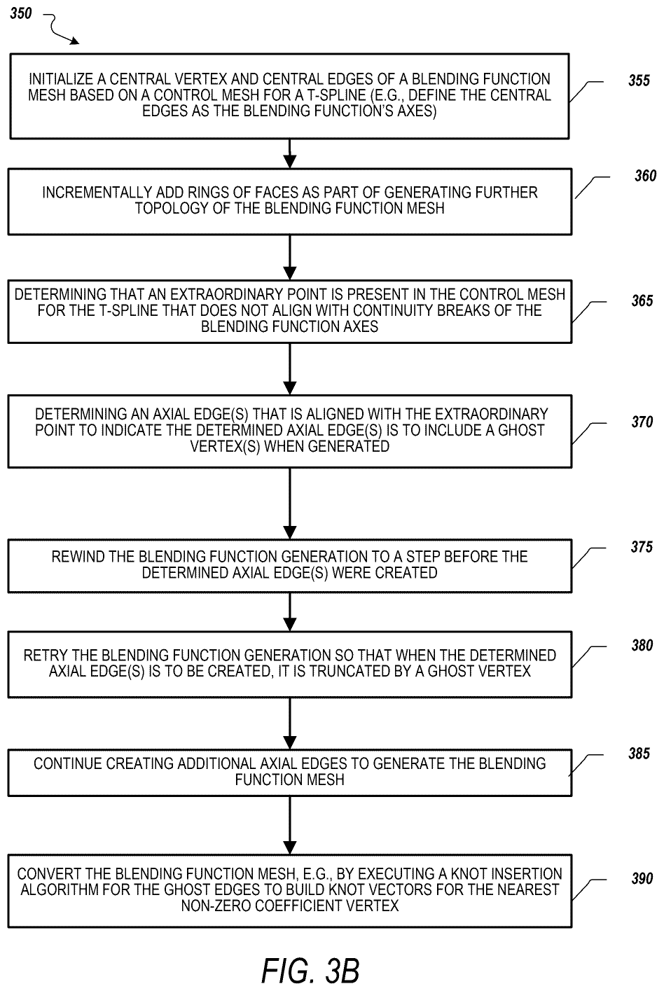

FIG. 3A shows an example of a process 300 that produces a T-spline surface from a control mesh by generating a blending function mesh in accordance with implementations of the present disclosure. In some implementations, the process 300 can be executed using a computer graphics application 116 (e.g., CAD, CAE, CAM, video production software, animation programs, or other). In some implementations, the computer graphics application can communicate with a manufacturing system, such as a CNC machine, or other subtractive manufacturing system, for production of physical objects based on a generated smooth surface from the operations performed at process 300. In some implementations, the computer graphics application can communicate with a digital projector (e.g., the digital projector 174 of FIG. 1) to provide a file (e.g., document of a particular expected format) that includes an output smooth surface from the process 300 for visual display by the digital projector. In some implementations, the computer graphics application can be a video production software solution that renders a 3D model and/or other models generated by a computer graphics application as a result of process 300 as part of a rendered scene or frame.

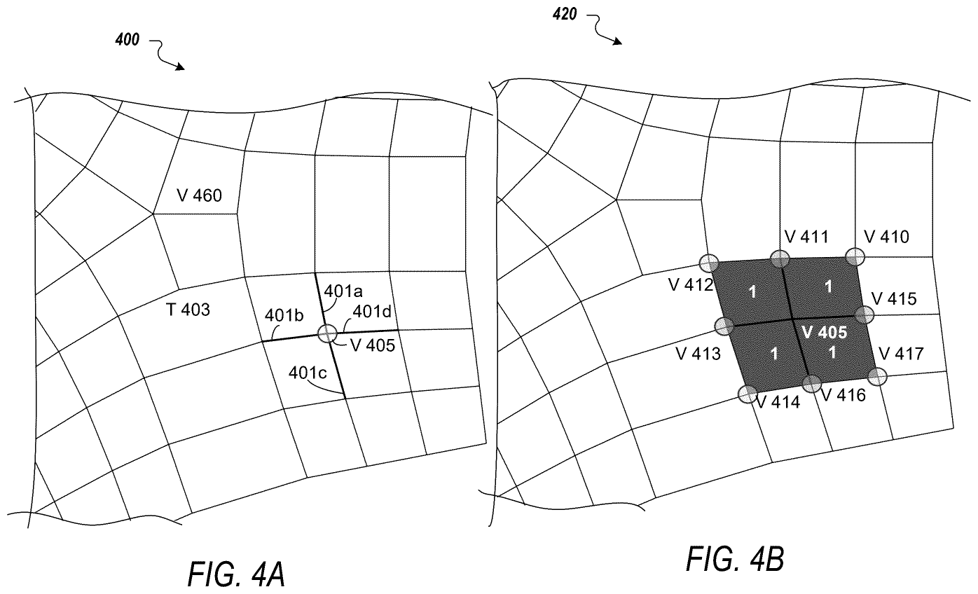

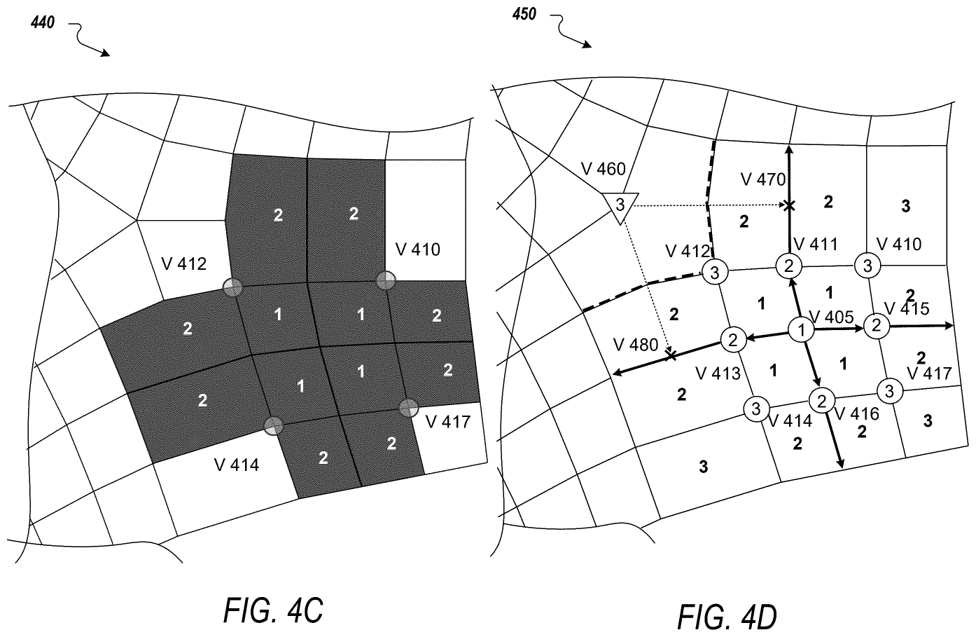

At 305, a control mesh for the T-spline surface is obtained. In some instances, the control mesh can be substantially similar to the control mesh 200 of FIG. 2A and/or the control mesh 220 of FIG. 2B. The control mesh can include T-junctions and extraordinary points. In some cases, a T-junction may have a location within a two-ring of faces around the extraordinary point. In some cases, the extraordinary point may be in the interior of a quadrant of the mesh. In such cases, directly inferring the blending function by determining axes of influence of the blending function starting from the central vertex as discussed in relation to FIG. 2B would not be possible. The process 300 generalizes the T-spline blending function inference algorithms such that the process 300 is applicable to cases where an extraordinary point occurs in a quadrant(s) of the blending function that is to be inferred. For example, and turning to FIG. 4A, the process 300 can be used to infer a blending function from the control mesh 400 of FIG. 4A that includes an extraordinary point V460 that is in a quadrant of the blending function of the central vertex V405. In the example mesh 400 of FIG. 4A, the extraordinary point is in the interior of the blending function mesh, or also called “engulfed” by the blending function. The presence of engulfment in a control mesh for a T-spline prevents the direct application of T-spline blending function inference algorithms to provide a working solution for inferring a blending function. To properly handle cases of such engulfment, the blending function for the T-spline surface can be inferred from a blending function mesh that is generated in accordance with the implementations of the present disclosure.

At 310, a blending function mesh is generated for inferring a blending function for a control point of the T-spline surface. The generation of the blending function mesh can be performed by defining a topology for the blending function mesh that can be inferred from the control mesh. The blending function mesh can be defined piecewise so that it is aligned with axial edges of the control mesh for the T-spline surface.

If in the control mesh 220 of FIG. 2B, the vertex V 230 was an extraordinary point, that extraordinary point will be axis-aligned with the continuity breaks of the T-spline blending function axes in both parametric directions. The extraordinary point V 230 corresponds to an existing continuity break. In general, if a T-spline does not include T-junctions, all extraordinary points would be axis-aligned.

In the example of the control mesh 400 of FIG. 4A, the extraordinary point V460 is “engulfed” as it is not aligned with the continuity breaks on the blending function axes. This is caused by the arrangement of the T-junction 403 close to the extraordinary point V460. In some instances, such non-alignment can be determined in either parametric direction or in both. To represent an “engulfed” extraordinary point in the topology of the blending function, the blending function mesh as generated at 310 includes topology that is inferred from the vertices and edges of the blending function mesh during its generation, which would include ghost edges and ghost vertices. Such topology is added to the blending function mesh to handle an identified engulfment in the blending function. While ghost edges and ghost vertices can be added to the blending function mesh to represent an “engulfed” extraordinary point in the topology of the blending function, generally, ghost edges and ghost vertices can be added to the blending function mesh to include a feature in the blending function mesh which is not aligned with the axial topology of the blending function. For example, such feature can include an n-gon center point or hole in the blending function.

At 315, a central vertex and central edges of the blending function mesh are defined as inferred from the control mesh. In the example of the control mesh 400 of FIG. 4A, the central vertex V 405 and the central edges 401a, 401b, 401c, and 401d are used to define a central vertex and central edges of the blending function mesh. In that portion, the blending function mesh will correspond to the control mesh 400. The blending function mesh can be generated to represent the three-dimensional points of the T-spline as vertices assigned with one-dimensional coefficients. The coefficients can be considered as the influence of the respective vertices on the surface, so that by modifying one of the coefficients for a vertex, the expected effect on the surface will correspond to the modification of the coefficient (e.g., to adjust the height of the surface at that point).

As part of the generation of the blending function mesh, further topology for the blending function is generated at 320, where the further topology is generated by directly inferring further faces and edges for the blending function from the defined central edges of the blending function mesh. The further generation of the topology of the blending function mesh can be performed as described in relation to the example for the control mesh 400 of FIG. 4A and through the steps described in relation to FIGS. 4A-4D.

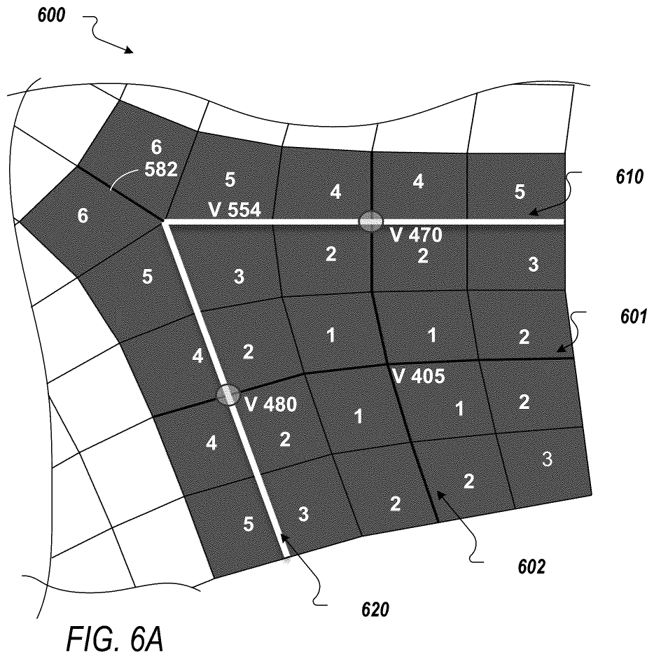

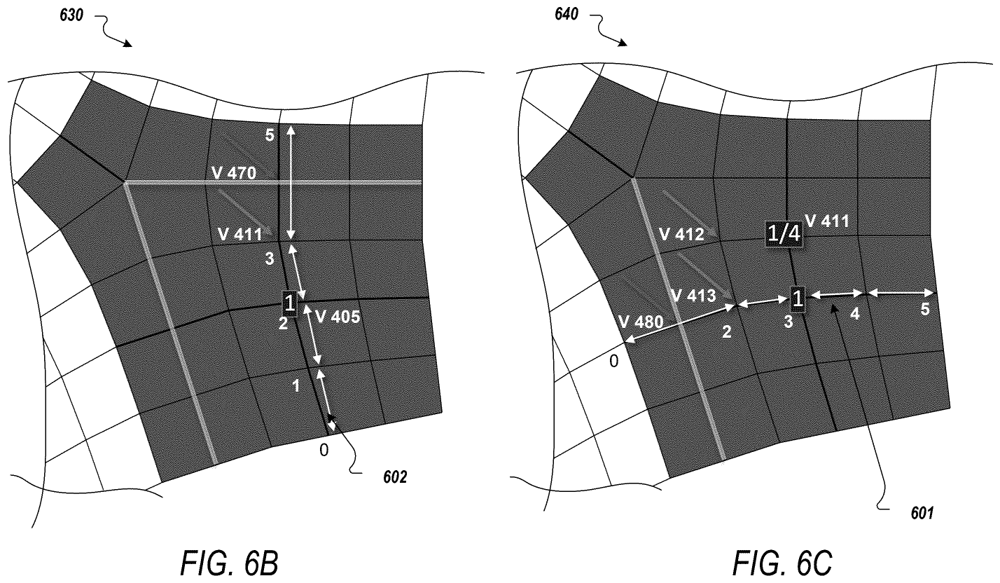

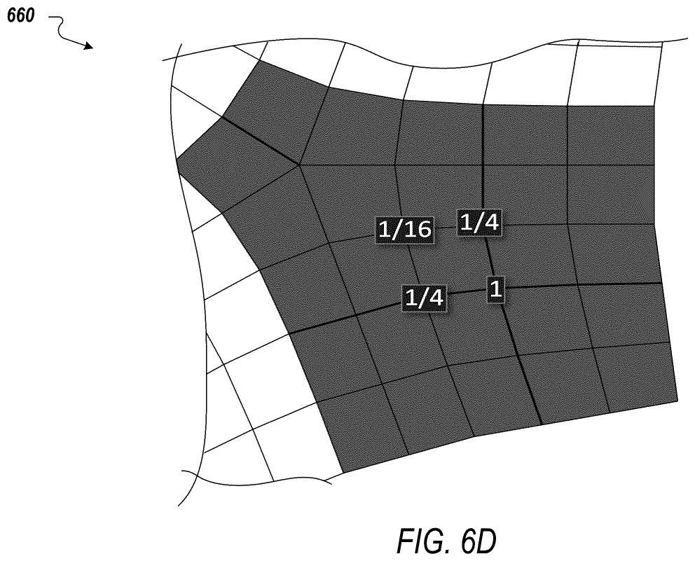

At 325, the blending function for the T-spline surface is inferred from the generated blending function mesh. In some instances, the blending function can be inferred by converting the multiplicity of rows or columns of edges on the control mesh from multiplicity “zero” to multiplicity “one”. In such case, the converting of the multiplicity can be performed to indicate that “ghost vertices” and “ghost edges” that are not part of the original control mesh (with multiplicity “zero” initially) can be included as regular vertices and edges through this conversion of their multiplicity to “one”. As such, the vertices and edges that are converted to multiplicity “one” are to be included as vertices and edges, while those that are with multiplicity “zero” are not included as regular vertices and edges during this conversion. For example, this conversion can be performed by materializing the ghost topology added to the blending function mesh, e.g., using a knot insertion algorithm. The conversion of the blending function mesh can be performed as described in relation to the conversion 390 of FIG. 3B, and/or as described in relation to FIGS. 6A-6D.

At 330, the inferred blending function is provided for use for computing the T-spline surface. The resulting blending function mesh has more than one vertex assigned with a non-zero coefficient at its center. For example, the blending function mesh generated for the control mesh 400 of FIG. 4A includes three vertices (besides the central vertex) that have non-zero coefficients, as shown on FIG. 6D. A non-zero coefficient describes how the respective vertex and modifications of its position can influence the underlying surface that is to be computed. The computation of the coefficients, for example, as described in relation to FIGS. 6A-6D, can allow use of the blending function mesh as a subdivision blending function.

In some implementations, based on the inferred blending function, the T-spline surface can be computed and rendered on a user interface, for example, of a display device. In some implementations, the rendered surface may be interacted with by the user 190. For example, the generated smooth surface can be used for manufacturing a physical object, e.g., using a CNC machine. In some cases, the generated smooth surface can be used to be rendered on a device (e.g., based on a user instruction or otherwise received from another application or service). In some instances, based on received instructions for use of the generated smooth surface, a toolpath specification can be generated based on the smooth surface, where the toolpath specification is then usable with an AM and/or SM machine 170 to build the physical structure or a cast or mold for the physical structure. In some other examples, the rendered smooth surface can be integrated into an animation scene or a video production.

In some implementations, the method for inferring a blending function based on generating a blending function mesh from a control mesh for a T-spline can be executed as described in relation to the example control mesh 400 that is used to generate a blending function mesh including ghost vertices to accurately represent the parameter space of the T-spline surface to which the blending function mesh is connected (and based on).

In general, in accordance with the present disclosure, to solve the engulfment problem associated with the topology of the control mesh for the T-spline, a blending function mesh can be generated with a topology that accurately represents the parameter space of the T-spline surface.

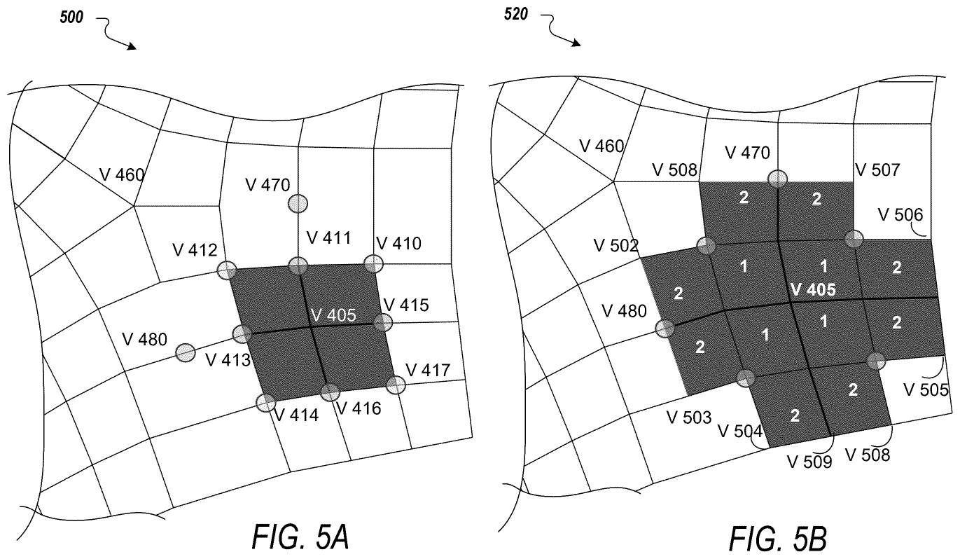

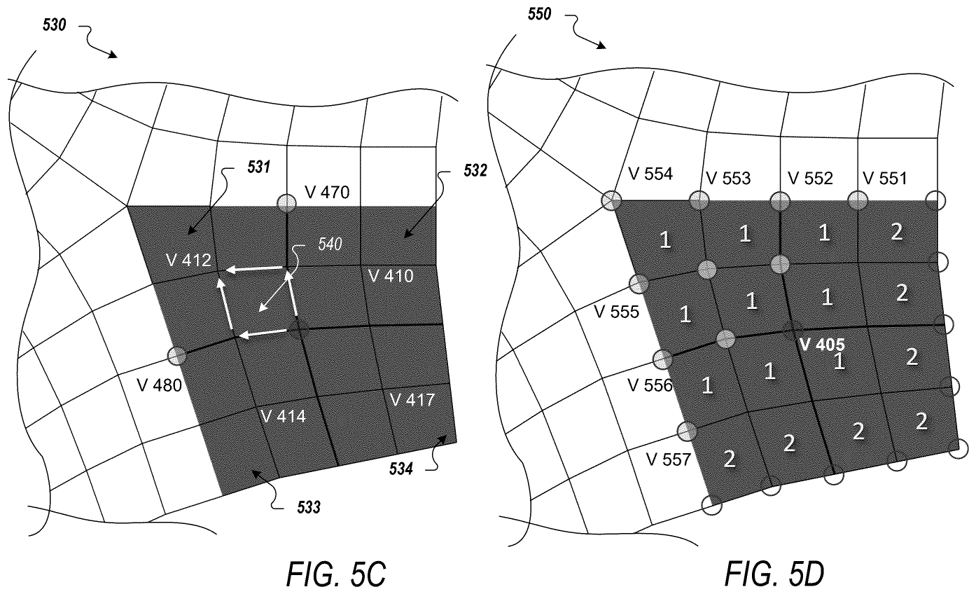

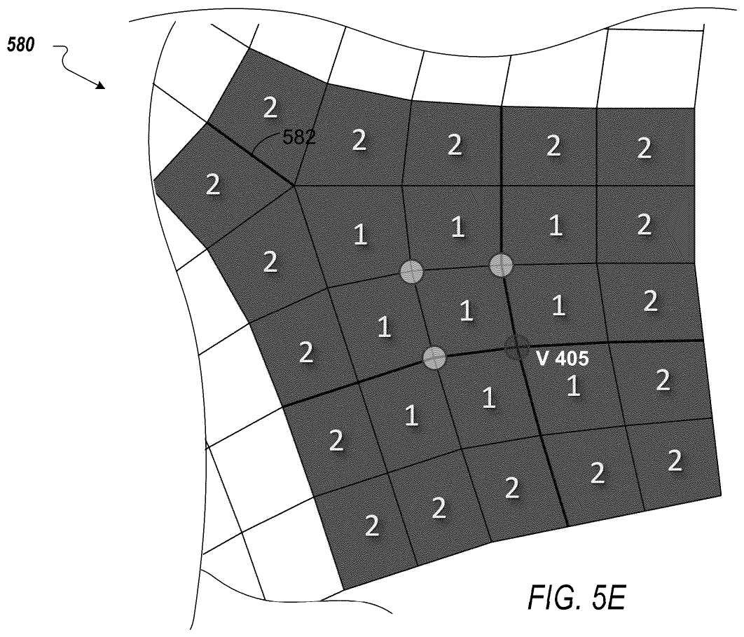

In some implementations, the execution of process 300 of FIG. 3A can be performed based on an implemented procedure to initialize a blending function mesh (e.g., as presented below in relation to Table 1), to process the control mesh to determine ghost topology (e.g., as discussed in relation to FIG. 3B, FIGS. 4A-4D, and in relation to Table 2), to generate such ghost topology for the blending function mesh (e.g., through the rewind and retry techniques as described further, e.g., in relation to FIGS. 3B, 5A-5E, and in relation to Table 4), and to materialize the ghost topology by running a knot insertion algorithm. The ghost topology can be considered as provided in the blending function mesh to enable inferring a blending function in a way that can solve engulfment problems which may otherwise prevent representing the T-spline surface accurately. The ghost vertices are added to the blending function mesh to represent engulfed points that are not aligned with the blending function's continuity breaks. The ghost topology can be considered as a placeholder for topology that has to be converted from multiplicity zero to multiplicity of one by using the knot insertion algorithm.

FIG. 3B shows an example of a process 350 that generates a blending function mesh for inferring a blending function to compute a T-spline surface in accordance with implementations of the present disclosure. In some implementations, the process 350 can be executed at a computer, for example, at a computer graphics application 116 (e.g., CAD, CAE, CAM, video production software, animation programs, other), or at another application communicatively coupled to the computer graphics application 116. In some implementations, the computer graphics application can communicate with a manufacturing system, such as a CNC machine, or other subtractive manufacturing system or technique, for production of physical objects based on a generated smooth surface from the operations performed at process 350. In some implementations, the process 350 can be implemented as part of the process 300 of FIG. 3A, where the operations of process 350 are performed for the generation of the blending function mesh at 310 of FIG. 3A.

At 355, a central vertex and central edges of a blending function mesh can be initialized based on a control mesh for a T-spline surface. In some instances, the initialization can be performed in response to obtaining the control mesh, for example, from a computer graphics application. The generation of the blending function mesh can be initiated based on a request for computing and/or rendering a T-spline surface that may include T-junctions and engulfed topology, as discussed throughout the present disclosure, and for example in relation to FIGS. 2A, 2B, and 3.

In some implementations, the initialization of the blending function can be performed according to operations of the initialization algorithm described at Table 1 below.

TABLE 1
Initialization

| 1. | Declare variables for the algorithm for generation a blending function mesh. The | |
|---|---|---|
| | declared variables are initially empty. The variables can be declared as follows: | |
| | a. | B is declared as the blending function mesh that is to be constructed. The |
| | | mesh can store: |

| | |
|---|---|
| i. | vertices, edges, and faces; |
| ii. | knot internals associated with each edge; |
| iii. | corresponding parametric location(s) on the control mesh for each |
| | vertex, edge, and face; |
| iv. | a coefficient for each vertex |
| v. | an “axial flag” for each vertex. |

| | |
|---|---|
| b. | S is declared to be used to hold a set of unconsumed (“unready’) seed vertices |
| | for a current neighborhood that is being inferred. These vertices are on the |
| | blending function mesh. |
| c. | Sᵣ is declared to be used to hold a set of seed vertices which are ready to have |
| | their faces inferred (a.k.a “ready” vertices). |
| d. | Sₙ is declared to be used to hold a set of seed vertices to be used for inferring |
| | a next neighborhood. |
| e. | G is declared to store the parametric locations of each of the ghost vertices. |
| | All are initially empty. Each vertex shall know its corresponding parametric |
| | location on the T-spline surface. |

| | |
|---|---|
| 2. | Create an initial blending function mesh B to include a single axial seed vertex, |
| | aligned with the T-spline control mesh vertex for which a blending function is |
| | inferred. Include that single axial seed vertex in S. |

With reference to FIG. 4A, a blending function is inferred for the vertex V 405 on the control mesh 400. The initial blending function mesh B for vertex V 405 would include a single axial seed vertex that aligns with the V 405. Based on the control mesh 400, central edges of the blending function mesh are added to correspond to the edges 401a-d that extend from the central vertex V 405 in the control mesh 400. When inferring the blending function for V 405 of the mesh 400, the blending function mesh B is initialized to include a central vertex and central edges to align with the axial edges of the control mesh, and such initial mesh B can be used to continue inferring topology for the blending function mesh B. The process can continue by adding face rings required by the blending function at 360. For example, for each face ring required by the blending function, a complete face ring algorithm in relation to operation 360 and as presented in Table 2 can be executed.

In some instances, the initialization process as presented in Table 1 can be executed according to the below Pseudo Code A to initialize the seed vertices and to invoke a “Complete face ring” procedure to iteratively perform the adding of the face rings until the full extent of the blending function is reached. In other words, when gₙ ghost vertices have been created along an axis of a degree d blending function, then the extending with further face rings shall be performed until

$$\frac{d + 1}{2} + {g}_{n}$$

axial edges have been created.

Pseudo Code A
ALGORITHM 1: Create Blending Function Mesh

```
  Input: Manifold T-NURCCS control mesh, SeedVertex
  Output: The blending function mesh associated with SeedVertex
  begin
    G ← ∅
    retry ← true
    while retry is true do
      retry ← false
      B ← Mesh containing only SeedVerte
      S ← (ScedVertex)
      $for neighborhood - 1 to \frac{d + 1}{2} do$
        Execute Complete Face Ring if retry then
          exit loop
        end
      end
    end
  end
```

At 360, rings of faces are incrementally added to the blending function mesh to generate further topology for the blending function mesh that is inferred from the blending function mesh. During the generation of the blending function mesh, ghost edges and ghost vertices can be included in the blending function mesh without those edges or vertices limiting the domain of the blending functions. The domain would not be limited since each ghost edge or ghost vertex has a knot multiplicity of zero, while each of the other edges and vertices of the blending function mesh has a knot multiplicity of one. The edge and vertices that are not ghost edges and vertices are aligned with the continuity breaks in the surface. The ghost topology can be considered to be added as part of the blending function mesh to allow representation of engulfed points that are not aligned with the continuity breaks of the blending function. In some instances, when variations of engulfment occur, it can be determined which vertices are treated as engulfed and the techniques for generating further topology for the blending function mesh can be applied.

In some implementations, when ghost edges and ghost vertices are added to the blending function mesh, ghost topology of multiplicity zero can be used for generating edges and vertices for the blending function mesh that would be converted to multiplicity of one by using the knot insertion algorithm. When constructing a knot vector in the presence of ghost topology (with multiplicity of zero), the ghost knots are omitted from the knot vector.

In some implementations, a blending function mesh can be generated that has more than one non-zero coefficient at its center describing how it influences the underlying surface. The resulting blending function can be processed as a subdivision blending function and used to compute the T-spline smooth surface.

In some implementations, the blending function generation can be created as a flood-fill process starting from the central vertex of the blending function mesh to initialize the blending function mesh. The blending function mesh can be further expanded by adding vertices and edges outwards to build it up face-by-face. The blending function axes are inferred from the central edges that are initialized for the blending function mesh, which also are inferred from the T-spline topology as in the control mesh that is obtained. The completion of the face rings as in operation 360 is performed through direct inference from the axes in the blending function and the resulting blending function mesh can include faces and edges that do not correspond to the underlying T-spline surface's faces and edges. As such, if an extraordinary point is identified on the T-spline and is also aligned with the continuity breaks in the blending function faces, an extraordinary point should also be added to the blending function mesh. Such tracking of points between the control mesh and the blending function mesh during the flood-fill algorithm is important for generating a blending function that correctly represents the T-spline surface.

In some cases, the addition of high-valence extraordinary points to the blending function mesh can result in topology whose dimensions cannot be inferred from the central axes of the blending function mesh. In such case, the topology should have its dimensions inferred from the T-spline surface and therefore, the blending function mesh can introduce additional axial edges, for example, as shown in relation to the example described for the control mesh 400 of FIG. 4A, and the additionally inferred axis edge 582 as shown in FIG. 5E. An axial edge can be defined as any edge in the blending function mesh whose knot interval was directly determined from the T-spline control mesh's topology. All other edges in the blending function mesh that are not axial can have their knot interval inferred from the axial edges.

This introduction of additional axial edges in the blending function mesh can support the generation of a blending function mesh where face counting rules can be applied, and a blending function can be inferred in a manner similar to using a subdivision mesh.

As previously discussed, the process for the blending function inference is backwards compatible with subdivision surfaces, NURBS surfaces, T-spline surfaces, and T-NURCCS surfaces. The process for generating a blending function mesh can be used for inferring the blending function to represent T-spline surfaces, where the T-spline control meshes can have topologies that include T-junctions and extraordinary points at particular locations that can be associated with engulfment problems. Such inference can be associated with fewer resources for the blending function inference and more accurate representation of complex T-spline surfaces.

At 365, it is determined, during adding topology to the blending function mesh, that an extraordinary point is present in the control mesh for the T-spline (the T-spline has a star point), and the extraordinary point does not align with the continuity breaks of the blending function. For example, such a determination can be made when topology is incrementally added for a blending function mesh generated based on the control mesh 400 of FIG. 4A, and the second ring of faces is added in the blending function mesh and where one of the vertices of the control mesh that is to be added to the blending function mesh is an extraordinary point, i.e., V460.

Table 2 below represents an example process for completing face rings that can be executed after the initialization process, for example, as described in Table 1. Step 4 of the process for completing face rings also considers whether an extraordinary point is present in the control mesh, which is a consideration for the method 350 and further describes in relation to operations 370, 375, and 380 and the expand central vertices procedure and the rewind and retry procedure. Table 3 below describes a procedure for expanding central vertices of the blending function mesh in accordance with the present disclosure, and for example, when an extraordinary point is engulfed in the topology of the T-spline. The steps of the procedures can be mapped to the processing steps performed for the control mesh 400 of FIG. 4A and described in relation to FIGS. 4A-4D.

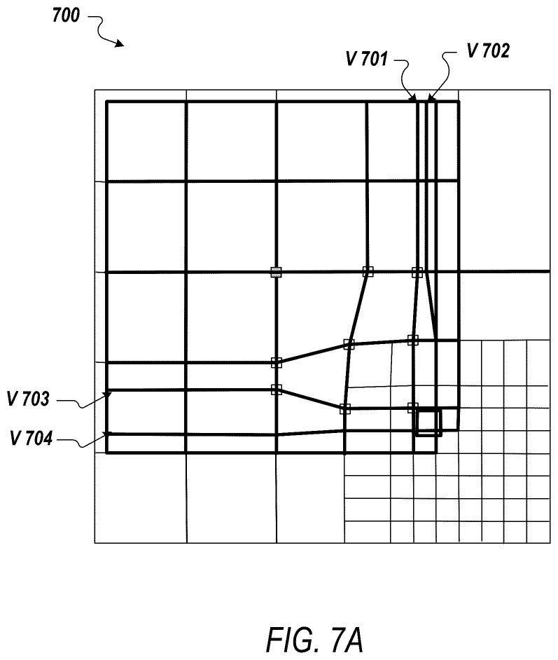

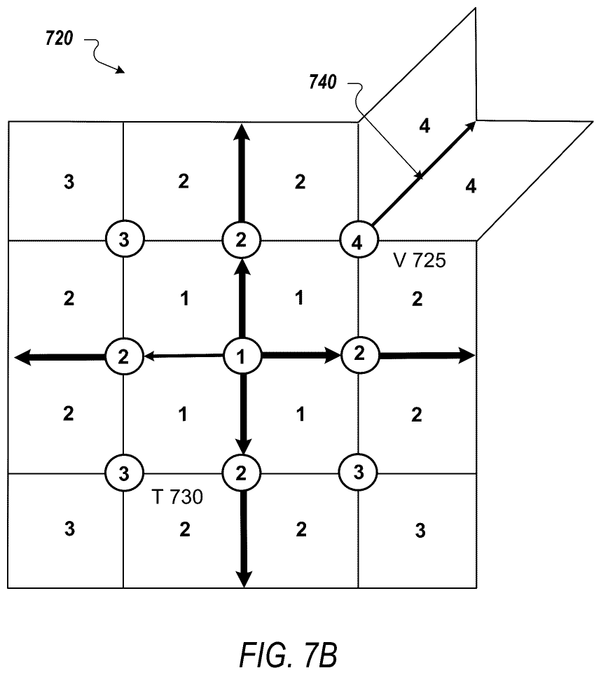

TABLE 2
Complete face rings

| 1. | Analyze S to find all vertices which are axial, or which touch two open edges that | |
|---|---|---|
| | require only a single additional face. Move all such vertices from S (unready vertices | |
| | that are not axial vertices) to Sᵣ to form the vertices that are to be used for inferring | |
| | the next faces. | |
| 2. | If no vertices were moved to Sᵣ but some vertices remain in S, mark all vertices in S | |
| | as axial and move them to Sᵣ. This step will move vertices that are on concave | |
| | corners into the set of vertices to be used for inferring the blending function mesh | |
| | faces. | |
| 3. | For each vertex in Sᵣ, create axial edges in each direction for which the blending | |
| | function mesh does not already have a corresponding edge to a corresponding edge | |
| | in the control mesh of the T-spline. See FIG. 4C and FIG. 7B as examples of the | |
| | next faces that are created in accordance with this step. The length of these edges | |
| | can be determined by finding the next continuity break on the T-spline surface. If | |
| | an axial edge would intersect with any ghost vertex G, its length is instead truncated | |
| | such that it has the closest such ghost vertex at its tip. Empty Sᵣ. | |
| 4. | Create faces between each existing edge which does not yet have a face, and which | |
| | corresponds to a corner in the T-spline surface. See FIG. 4D for reference for | |
| | performing this step, where the next face to be created extending from vertex V 412, | |
| | engulfs an extraordinary point. Store the alignment of each such face and add all | |
| | additional created vertices to Sₙ. | |
| | a. | If, during the creation of any such face, an engulfment is observed (e.g., as in |
| | | FIG. 4D), a Rewind and Retry algorithm can be invoked for execution, as |
| | | described in relation to operations 375 and 380 of FIG. 3B, and for example, |
| | | as presented in Table 4 below. |

| | |
|---|---|
| 5. | If any of the axial edges created in step 3 were truncated by a ghost vertex, execute |
| | the Expand Central Vertices algorithm as described in more detail in relation to |
| | operation 370 of FIG. 3B and Table 3 below. |
| 6. | If any vertices remain in S, repeat from step 1. |
| 7. | Move all vertices in Sₙ to S. If this is not the final neighborhood, proceed to the next |
| | one (see Initialization step 3 in Table 1) to continue with creating the next |
| | neighborhood. |

In some instances, the complete face rings process as presented in Table 2 can be executed according to the below Pseudo Code B to expand the blending function mesh after the initialization and to iteratively perform the adding of the face rings until the full extent of the blending function is reached.

ALGORITHM 2
Complete Face Ring

```
Input: S. Sᵣ, Sₙ, G, B
Output: Expanded B
begin
  Sᵣ ⇐ all vertices in S which are axial or ready.
  while S is not empty do
    if Sᵣ is empty and S is not empty then
        Mark all vertices in S as axial
        Sᵣ ⇐ S
    end
    for each vertex [symbol]  in Sᵣ do
        Create new axial edges on [symbol]  for each direction where B
          doesn't have a corresponding edge.
        if any created axial edge intersects with G then
          Truncate the edge to the nearest such position
          Mark the tip as a ghost vertex
        end
        for cach edge e [symbol]  on [symbol]  do
          if there is no face between e [symbol]  and e [symbol]  on B and
            there is a face at that location on the T-spline
            surface then
              Create a face in B and create a map between it
                and the T-spline surface
              if creating the mapping fails then
                  Execute Rewind and Retry
                  Exit algorithm
            end
          end
        end
    end
    if any created axial vertices were truncated by a ghost verter
      then
        Execute Expand Central Vertices
    end
  end
  S ⇐ S [symbol]
end
Pseudo Code 2 [symbol]
indicates data missing or illegible when filed
```

At 370, an axial edge is determined that is aligned with the extraordinary point (in the example of FIGS. 4A-4D, that is V460), and the determined axial edge is as the axial edge 582 shown of FIG. 5E and as described in relation to operation 3 of the complete face ring algorithm at Table 2 above. Table 3 below describes a process for expanding the vertices when ghost vertices are identified, as they are pointed back from an encountered engulfed extraordinary point back to the axial edges.

TABLE 3
Expand central vertices

| | |
|---|---|
| 1. | For each ghost vertex at the tip of an outer axial edge, trace along the axial edges |
| | inward toward the central vertex or vertices (i.e., those vertices which have been |
| | marked as needing non-zero coefficients). Note the first central vertex which is |
| | encountered. For example, at FIG. 4D, when the ghost vertices V470 and V480 are |
| | encountered, the axial edges are tracked back to previously added vertices on axial |
| | edges, in that example, central vertex V405.. |
| 2. | From that first central vertex, extend the set of central vertices out one additional row |
| | toward the ghost vertex. With reference to the example of FIG. 4D, from the central |
| | vertex V405, the central vertices are extended out to add vertices V411 and V413. |
| 3. | Label each face touching a central vertex with a 1, and then incrementally label each |
| | additional vertex-connected face outward to determine which face rings are |
| | complete. For example, the labelling can be performed as shown at FIG. 5D that |
| | shows labelling after expanding the central vertex V405 to have more than one |
| | central vertex.. |
| 4. | All faces on the exterior of the blending function mesh whose label is less than that |
| | of the face ring of the respective neighborhood that is currently filled need to be |
| | extended by an additional ring (see Initialization process of Table 1 at step 3). Find |
| | all vertices which are on these faces, and which are found in Sₙ and move them to S. |

At 375 and 380, a rewind and retry technique is applied. The rewind and retry can be performed, for example, as described at the procedure presented in Table 4.

The rewind and retry technique can be requested for execution whenever an engulfment is determined to be existing in the topology that has to be inferred in the blending function mesh, for example, when an extraordinary point is encountered in the T-spline surface that does not align with the continuity breaks of the blending function axes. At that step, the generation of the blending function mesh can continue by considering adding topology based on the T-spline surface even if such topology is not present in the control mesh that is obtained for the T-spline. A ghost vertex can be created by computing which axial edges are parametrically aligned with the extraordinary point (there may be more than one such edge). And those axial edges can be marked as needing a ghost vertex. For example, such marking can be performed as shown in the example of the mesh 400 of FIG. 4A, when the process is inferring topology for the engulfed extraordinary point 460 at FIG. 4D, and the marked edges are the edges that include the ghost vertices V470 and V480.

When the ghost vertices are identified and the axial edges are marked, a rewinding 375 of the blending function initialization process can be performed to revert the topology generation for the blending function mesh to a point before that axial edge(s) were created. For example, the rewinding can revert to the initialization as shown in relation to FIG. 5A, where when the ghost vertices are marked, the topology is reverted to the state as shown in FIG. 5A, and on the next iteration of adding faces (the retry step), the added vertices and edges to the blending function mesh will include respective vertices and edges as created topology for the blending function mesh. As such, the process of retrying the blending function initialization from that point, e.g., as shown at FIG. 5A, will continue with adding more axial edges, e.g., as shown at FIG. 5B. When the axial edge is next created, it will be truncated by the ghost vertex. Table 4 below presents steps of the rewind and retry technique that can be applied when generating a blending function mesh to infer a blending function.

TABLE 4
Rewind and Retry

| | |
|---|---|
| 1. | Determine a parametric location of an identified engulfed topology item (e.g., an |
| | extraordinary point, such as the engulfed vertex 460 of the examples of FIGS. 4A- |
| | 4D) and trace isoparametric lines across the existing mesh topology until an |
| | intersection with an axial edge is found (e.g., as shown at FG. 4D). |
| 2. | Add the parametric location of the ghost vertex to G. |
| 3. | Clear the contents of S, Sᵣ, Sₙ, and the blending function mesh topology (but retain |
| | the contents of G). Restart the algorithm from step 2 of Initialization and retry for the |
| | blending function mesh after the rewinding as shown at FIG. 5A with regard to |
| | vertices V470 and V480 that are ghost vertices. |

At 385, additional axial edges continue to be created to generate the blending function mesh. The addition of high-valence extraordinary points to the blending function mesh can result in topology whose dimensions cannot be inferred from the central axes, for example, as in the examples of FIG. 4A-4D and FIG. 5A-5E. This added topology (the ghost vertices and the ghost edges) should have its dimensions inferred from the T-spline surface and can introduce additional axial edges. This introduction of additional axial edges makes the process of the blending function generation substantially equivalent to the face counting rule that can be used to infer subdivision-like blending functions.

At 390, the blending function mesh is converted so that included ghost edges and ghost vertices in the blending function mesh are converted from multiplicity zero to multiplicity one. This conversion process of the ghost topology can be referred to as materializing the ghost topology. In some instances, the conversion can be performed by executing a knot insertion algorithm for the ghost edges by building knot vectors for the nearest non-zero coefficient vertex. After the blending function mesh is generated and includes ghost topology, the additional ghost topology can be converted from multiplicity zero to multiplicity one. In such manner, the blending function is inferred from a blending function mesh that has non-zero multiplicity for included extraordinary points (after the conversion is executed). In some instances, the conversion can also be performed through using an inference method for computing the blending function based on rules that interpret the influence of extraordinary points in a blending function mesh that are with multiplicity zero.

In some instances, the materialization of the ghost edges can be performed by executing a knot insertion algorithm. The knot insertion can include defining a knot vector from the nearest non-zero coefficient vertex on the blending function mesh and then inserting a knot at the ghost vertex to convert it from multiplicity zero to multiplicity one. The result is a blending function mesh that has more than one non-zero coefficient at its center describing how it influences the underlying T-spline surface. This allows treatment of the resulting blending function mesh as a subdivision-like blending function.

FIGS. 4A-4D, 5A-5E, 6A-6D represent operations for generate a blending function mesh based on an example of a control mesh 400 as shown in FIG. 4A. The blending function mesh is used to infer a blending function to compute a smooth surface.

As previously described, the control mesh 400 as shown at FIG. 4A is an example of a topology of a T-spline surface that includes an extraordinary point and a T-junction that falls within a two-ring of faces around the extraordinary point. In some of FIGS. 4A-4D, 5A-5E, 6A-6D, the vertices are presented with annotations of numbers that show the order in which they are processed to create subsequent rings of faces as part of adding further topology to the blending function mesh, e.g., as described in relation to the generation step 310 of FIG. 3A, and the steps 360, 365 and 370 of FIG. 3B, as well as, as presented in Table 2.

FIGS. 4A-4B are related to the initialization of a blending function mesh based on an obtained control mesh 400 for a T-spline surface. Once the control mesh 400 is obtained, an initialization procedure can be started. The control mesh 400 is for a T-spline and includes a T-junction vertex, i.e., T 403, and an extraordinary point V460, where the T-junction 403 falls within a two-ring of faces around the V460. The control mesh 400 can be the control mesh that is obtained at operation 305 of FIG. 3A, and can be used to infer a blending function mesh, for example, as described in relation to the process 300 of FIG. 3A and the process 350 of FIG. 3B.

In the control mesh 400, the extraordinary point appears mid-edge, and thus it will be engulfed by a blending function generated for the V 405. The vertex V 405 is the blending function center and can be considered as the initial seed point to be added during the initialization process as described above in relation to FIGS. 3A and 3B, and in Table 1. The initial four axial edges that are used to generate corresponding axial edges in the blending function mesh are the edges 401a-d.

For the sake of the example and to facilitate the understanding, a blending function mesh is created based on the control mesh 400 of FIG. 4A, where the generation of the blending function mesh is shown in FIGS. 4B-4D, 5A-5E, 6A-6D as an annotation over the control mesh 400 to indicate the topology of the blending function mesh. The blending function mesh is aligned with the topology of the T-spline surface. As shown, some vertices and edges during the blending function mesh creation will correspond to existing vertices and edges in the control mesh, but other will not be part of the control mesh and those will correspond to additional topology added to the blending function mesh to allow the inference of the blending function to be compatible with the subdivision surfaces and with NURBS surfaces, as well as with T-spline surfaces, and T-NURCCS surface. Based on applying techniques of the present disclosure, useful results for computing the T-spline surface are provided that optimize the computational time and the resources used (e.g., time and processing resources).

It should be understood that the blending function mesh is a separate mesh that is generated based on the control mesh 400 and the discussion of the blending function mesh as described for FIG. 4A-4D, 5A-5E, 6A-6D is with reference to the underlying control mesh just for the sake of case of understanding.

FIG. 4B shows a view 420 of a next iteration during the initialization of the blending function mesh from FIG. 4A, where the first set of vertices to be considered for expansion are labeled. FIG. 4B shows an annotation over the presented control mesh 400 as an overlay to refer to the respective blending function mesh vertices and edges as annotated (the seed vertices of the blending function mesh are circled on top of the control mesh 400).

A 1-neighborhood is generated for the blending function mesh to expand the topology. There are four added faces and those are highlighted. The 1-neighborhood includes vertices V 410, V 411, V 412, V 413, V 414, V 415, V 416, and V 417. Some of the vertices are axial vertices (those are V 411, V 413, V 416, V 415) and those vertices are “ready” (the next set of vertices from which to infer further faces) to have their faces inferred, and some of the vertices are not ready, as they are not axial and are not concave corners (those are V 410, V417, V 414, V 412). As discussed in relation to the initialization procedure of Table 1, at step 1, the ready vertices are added into Sᵣ as part of the set of seed vertices to initiate inference of further faces for the blending function mesh. For those ready vertices, i.e., V 415, V 416, V 413, and V411, a complete face ring procedure as described in relation to Table 2 can be invoked. For each of these vertices in Sᵣ (including axial vertices or vertices that touch two open edges that require only a single additional face), axial edges are created in the direction for which the blending function mesh does not already have corresponding edges.

FIG. 4C shows a view 440 representing the generation of the axial edges based on the four vertices from FIG. 4B that are seed vertices (since they are axial). FIGS. 4C-4D show a process of expanding the topology of the blending function mesh, for example, as described in relation to operation 320 of FIG. 3A, operations 360 to 370 of FIG. 3B, and Table 2 above. In FIG. 4C, an expansion of the topology of the blending function mesh is done for the 2-neighborhood. The expansion is performed with regard to those vertices from FIG. 4B, that are ready, and eight (8) more faces are added that are labeled as the second ring of faces around the central vertex. The circled vertices in FIG. 4C are those vertices that were not ready for processing at the previous step. Since more faces are built as part of the 2-neighborhood, the circled vertices corresponding to the V 410, V417, V 414, V 412 of FIG. 4B are determined as ready (to proceed to infer further faces) since they are now at concave corners. Those vertices can be considered as the third set of seed vertices to be processed to expand the topology of the blending function mesh.

FIG. 4D shows a view 450 with an expansion of the topology of the blending function for the vertices V 412, V 432, V 417, and V 410. The vertices are seed vertices and are used for processing during the expansion, and those vertices are labeled with the number three (3) since those are the third set of vertices that are processed to generate further topology for the blending function. FIG. 4D shows an example iteration at the expansion algorithm in which ghost vertices are required. During expanding the blending function mesh on the upper-left portion to expand a face from the vertex V412 and connected blending function mesh edges, a non-aligned extraordinary point V460 is found. The point is annotated with a triangle and numbered with 3. The V460 is engulfed in the blending function. When such an extraordinary point is determined, as described for example in relation to operation 365 of FIG. 3B and the step 4 of Table 2, a rewind and retry process as previously described can be triggered.

At that state of the generation of the blending function mesh as shown in FIG. 4D, the generation of the blending function mesh can continue by considering adding topology based on the T-spline surface even if such topology is not present in the control mesh that is obtained for the T-spline. A ghost vertex can be created by computing which axial edges are parametrically aligned with the extraordinary point (there may be more than one such edge). In the example, two ghost vertices, V470 and V480 can be considered and marked on those axial edges, so that when the rewind and retry procedure is executed, the ghost vertices are to be used for generating topology for the blending function mesh. The ghost vertices are determined as the locations on the axes of the blending function that are affected by the extraordinary point.

FIGS. 5A-5E show states of the blending function mesh during the rewind and retry procedure and in the context of processing the control mesh 400 of FIG. 4A. The described example of a rewind and retry procedure at FIGS. 5A-5E shows how the topology of the blending function mesh is adjusted (reverted one step back with the rewind, and build again with additional topology based on considerations for the identified engulfment in the control mesh). The adjustment can be performed based on inferring vertices and edges from the topology of the T-spline.

FIG. 5A shows how the blending function mesh is reverted back to the state as shown in FIG. 4C. FIG. 5A shows a state 500 of the blending function mesh where a rewind operation can be executed. Based on determining to add the ghost vertices 470 and 480 to the blending function mesh, the process is reverted to a previous step before generating 2-neighborhood faces (8 faces generated at the step of FIG. 4D). The state 500 of the blending function mesh includes the 1-neighborhood faces and the knowledge for ghost vertices, as identified and described in relation to FIG. 4D.

FIG. 5B shows a next state 520 of blending function mesh based on generating additional topology to the topology included in the blending function mesh at the state 500 as shown in FIG. 5A. A retry step can be executed (as described above) and addition of faces can be performed. The state 520 of the blending function mesh includes added vertices and edges to the blending function mesh related to the 2-neighborhood expansion. The axial edges are truncated by ghost vertices, for example, as described in step 5 of the rewind and retry procedure of Table 2 for completing new faces to be added to the blending function mesh. This additional topology allows the algorithm to run to completion.

The vertices V470 and V480 are added as inferred from the ghost vertices that were identified, for example, as described in relation to FIGS. 3A, 3B, and 4D. The vertices V 505, V 506, V 507, V 470, V 508, V 502, V 480, V 503, V 504, V 508, V 509 are added to the blending function mesh to form the 2-neighborhood. This 2-neighborhood as shown in FIG. 5B is different from the 2-neighborhood previously generated as shown in FIG. 4D as it adds further topology to the blending function mesh that is not part of the control mesh. However, the 1-neighborhood stays untouched, as the process reverts to the previous vertices, V 410, V 111, V412, V413, V 414, V415, V416, and V417 that are at the outside of the 1-neighborhood of faces. The process of retrying the blending function initialization from that point, e.g., as shown at FIG. 5B, will continue with adding more axial edges, e.g., as shown at FIG. 5C.

FIG. 5C shows a next state 530 of the generation of additional topology for the blending function mesh 500 of FIG. 5A as part of the rewind and retry process. At this state 530, the vertices V410, V412, V414, and V417 are ready vertices that can be filled and the upper left and right faces (531 and 532) and lower left and right faces (533 and 534) are added to the blending function mesh with their respective vertices and edges. At this iteration, 2-neighborhood seeds are exhausted and the 2-neighborhood of faces are completed. The ghost vertices that are added to the blending function mesh can later be materialized (as described in relation to operation 390 of FIG. 3B) e.g., via knot insertion.

The knot insertion will affect the coefficients assigned to the vertices. Initially the central vertex is assigned with a coefficient 1 and all the other vertices are 0. As discussed, the added ghost vertices also have zero multiplicity. When the knot insertion is performed, some of the coefficients will become non-zero, in particular, for the face 540, annotated with the arrows. The central vertex V405 will “pass” some influence to these three additional vertices.

At state 530, three vertices do not yet have a full 2-neighborhood, i.e., the vertices of face 540 apart from the central vertex. The filling out of the 2-neighborhood can proceed, and seed vertices for the 3-neighborhood can be stored.

FIG. 5D shows a next state 550 where a definition of the seed vertices to proceed the generation of the blending function mesh are defined. Due to the inclusion of the new ghost vertices, some of the seed vertices at this state 550, which are used to continue expanding the faces, are now adjacent to 1-neighborhood faces. In general, the seed vertices at this state 550 are all the vertices at the end of the generated faces. The faces part of the blending function mesh at this state 550 are labeled as to the neighborhood (in the present example 1 or 2) to which they belong. The vertices V551, V552, V553, V554, V555, V556, and V557 are such vertices that are adjacent to 1-neighborhood faces, while the rest are adjacent to 2-neighborhood faces.

To proceed with the generation of topology for the blending function mesh, the seed vertices for generating the 3-neighborhood (those that are adjacent to 2-neighborhood faces) are labeled as 2-neighborhood seeds, as described in step 4 of Table 3 discussing the process of expanding the rings of faces. By labeling the vertices V551, V552, V553, V554, V555, V556, and V557 as seed vertices for the 2-neighborhood, the process of expanding the faces can continue and further faces can be generated as shown in FIG. 5E.

FIG. 5E shows the final blending function topology 580 in accordance with the example control mesh 400 of FIG. 4A. The blending function topology 580 includes central vertices marked with circles and an extended 2-neighborhood of faces that are labeled.

FIGS. 6A-6C show an example execution of a knot insertion algorithm to generate the final blending function based on the topology generated for the blending function mesh as shown at FIGS. 5A-5E. FIG. 6D shows an example of a blending function mesh generated after the execution of the knot insertion at FIGS. 6A-6C.

FIG. 6A shows a view 600 of the blending function topology 580 of FIG. 5E with two ghost isolines 610 and 620 that were created because of the inclusion of ghost vertices (470 and 480) in the blending function mesh. The blending function mesh has two axes 601 and 602. Based on the current blending function topology 580, a B-spline knot insertion algorithm can be executed to materialize the ghost isolines 610 and 620. The ghost isolines 610 and 620 are traces from the parametric location of the engulfed topology item (i.e., the extraordinary point 554 of FIG. 5D) across the existing mesh topology of the blending function mesh until an interaction with an axial edge is found. The intersection is at the ghost vertices.

FIGS. 6B and 6C show views of the blending function mesh that shows how knot insertion is performed to determine how to convert the multiplicity of ghost topology from multiplicity zero to multiplicity one. This process is also called materialization as described above, as is performed for the two ghost vertices that are added to the blending function mesh (circled vertices 470 and 480 in FIG. 6A). The vertices are assigned with coefficients, where the central vertex is with coefficient 1, and the rest are with coefficient zero. A knot insertion algorithm can be run to build knot vectors for the nearest non-zero coefficient and then insert a knot at the ghost vertex to convert it from multiplicity zero to multiplicity one.

The blending function is associated with knot vectors, which are centered around the original blending functions center (V 405). FIG. 6B shows the first knot vector at view 630 of the blending function mesh. FIG. 6C shows the second knot vector at view 640 of the blending function mesh. The two views are associated for the two knot vectors over the two axes.

At FIG. 6B, the knot vector is shown with the arrows along the axis 602 and is [0 1 2 3 5]. A knot is inserted at t=4, which is at the location of the ghost vertex V470. Updated coefficients are computed for the vertices. The original vertex V405 is maintained with coefficient 1, while a new coefficient of ¼ is assigned to the vertex V411, as shown on FIG. 6C.

FIG. 6C shows the materialization of the second ghost vertex V480 as shown in FIG. 6A. FIG. 6C shows the knot vector by the horizontal arrows along the axis 601, where the knot vector is defined [0 2 3 4 5]. A knot is inserted at t=1 (at the location of the ghost vertex 480), where the arrow points out to the vertex V480. Updated coefficients are computed and two additional non-zero coefficients are computed for the vertices 413 and 412, that are ¼ and 1/16 as shown on FIG. 6D.

FIG. 6D shows a view 660 of the final blending function with the computed coefficients based on the example generation procedure as described in relation to FIGS. 4A-4D, 5A-5E, and 6A-6D. The coefficients are computed for face 540, where the vertex V 405 is with a coefficient 1 (maintained), and the coefficients for vertices V 413, V 412 and V 411 are respectively ¼, 1/16, and ¼. At the final blending function, the non-zero coefficients are assigned to the central vertices of the blending function mesh as shown at the view 660.

In some examples, the blending function may engulf more than one extraordinary point, and multiple ghost edges will thus be marked during the process, so that the rewind and the retry algorithm can be invoked several times before the final blending function topology is generated.

FIG. 7A shows an example of a resultant blending function mesh 700 that is generated according to techniques of the present disclosure, for example, according to the process 300 and the process 350 of FIGS. 3A and 3B. The blending function mesh 700 is shown as an overlay on the control mesh, where the blending function mesh 700 topology is presented with a dotted line. The mesh 700 is obtained after encountering multiple extraordinary points, i.e., so that several ghost vertices were added, i.e., V 701, V 702, V 703, and V 704. The blending function mesh includes nine (9) central vertices (marked in squares) that resulted from materializing the ghost vertices. In this example, building the 2-neighborhood for the central vertices led to complex results where the bottom right face appears to be “missing”, which is correct since that is in the 3-neighborhood. A computed visualization of the blending function for the mesh 700 corresponds to the 3D model 132 of FIG. 1.

FIG. 7B shows an example of a blending function mesh 720. The vertices in the blending function mesh 720 are annotated the respective number of their processing to be added to the blending function mesh in accordance with the techniques for generation a blending function mesh as described in relation to FIGS. 3A-3B, 4A-4D, 5A-5E, and 6A-6D. The mesh 720 includes an extraordinary point (i.e., vertex V725), marked as 4 (the iteration when the vertex was added as part of the seed vertices to be processed), and the other vertices are annotated based on the order of their processing for inclusion in the blending function mesh. In the example of FIG. 7B, the blending function mesh 720 shows that the blending function engulfs the single axis-aligned extraordinary point, vertex 725.

In addition to the eight central axial edges, a ninth axial edge, edge 740, was added during the generation of the blending function mesh. Vertex V725 was made axial, in accordance with performing operation 2 of the complete face ring algorithm as shown at Table 2, and the edge 740 was made an axial edge, in accordance with performed operation 3 of the complete face ring algorithm as shown at Table 2. The term “axial edge” implies that the continuity breaks of the blending function are inferred from the underlying topology on the T-spline surface at these locations.

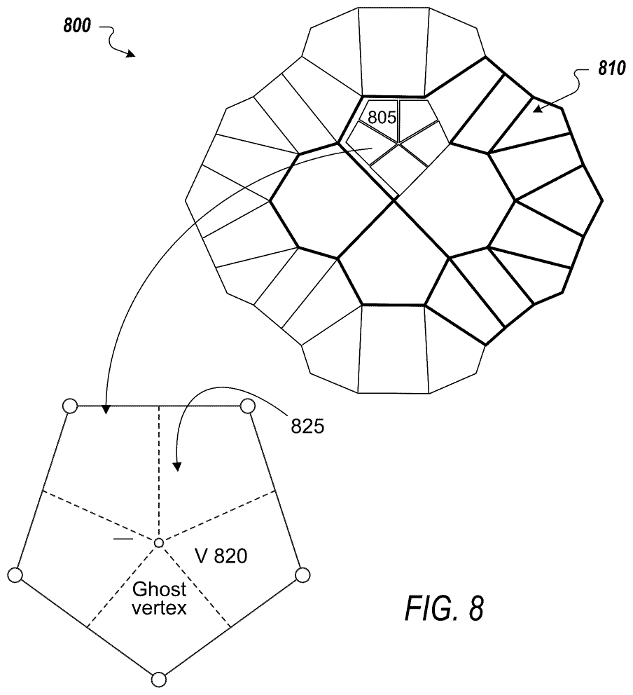

FIG. 8 shows a blending function mesh 810 generated based on a control mesh 800, where the control mesh 800 includes N-gons such as the N-gon 805. In the present example, when the blending function mesh is generated, some of the edges of the blending function mesh 810 are edges inferred from edges of the N-gon 805 of the polygonal control mesh. As shown, the N-gon 805 is a 5-gon, where subdivision of the 5-gon is performed to include an extraordinary point in the center of the 5-gon and to add a set of edges and vertices.

During generation of the blending function mesh 810, it can be determined that the N-gon 805 is engulfed by the blending function mesh. The edges of the N-gon 805 of the control mesh 800 do not align with axial breaks on axes of the blending function. Thus, generating further topology for the blending function mesh can be performed by defining a ghost extraordinary point (the ghost vertex V 820) for the N-gon 825 of the blending function mesh, as shown in FIG. 8. The definition of such a ghost extraordinary point can be performed by performing a subdivision of the N-gon 825 in the blending function mesh (the N-gon 825 corresponds to the N-gon 805 in the control mesh).

The extraordinary point V 820 can be created within the 5-gon 825 according to NURCC subdivision rules to define a subdivision that introduces the extraordinary point V 820 in the subsequently generated refined mesh based on the initial subdivision. For example, NURCC subdivision rules can be defined as described in “T-splines and T-NURCCs, Sederberg et al, ACM Transactions on Graphics, July 2003,” and in U.S. Pat. No. 7,274,364 to Sederberg, which are hereby incorporated by reference.

Further N-gons of the control mesh 800 can be processed in a substantially similar manner to generate further topology including ghost extraordinary points added to the blending function mesh, similar to the ghost extraordinary point V 820 for the N-gon 825 of the blending function mesh.

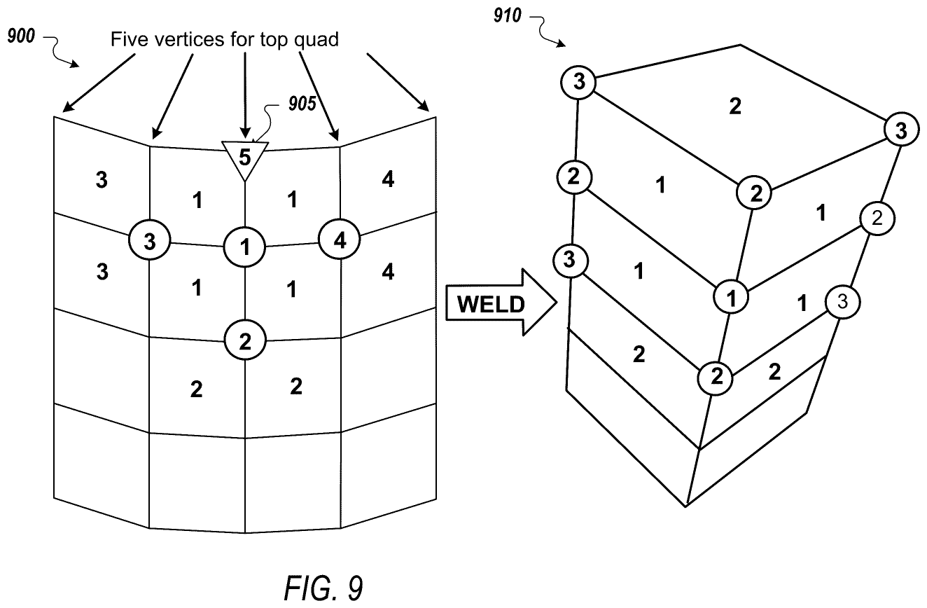

FIG. 9 shows a control mesh 900 for an object 910 including a vertex 905 determined to require a welding adjustment due to welding of some of the vertices and edges of the control mesh 900. When the control mesh 900 is welded as it forms a closed structure where the left-side edges of the control mesh 900 coincide with the right-side edges of the control mesh 900 to form the object 910. As such, the control mesh 900 includes five vertices at the top and at the bottom for covering a face that is a quad. In this example, the control mesh 900 can be associated with a welding problem when inferring the blending function. In the present example, the welding is inherent to the structure of the object, and the blending function mesh can be created with the understanding of the periodicity of the representation. The vertex 905 is illustrated with a warning triangle to indicate that during processing the vertex 905, it is determined that a “welding” adjustment is needed. In particular, during the generation of a face at the top of the cylinder, the vertices at the top of the blending function mesh are processed to identify a face. However, there are five vertices in this example, and the corresponding face in the control mesh to the top face to be formed in the blending function mesh only has four vertices. It should be appreciated that this is an example of a face with four vertices where other faces with fewer or more vertices may be processed as well. By applying a welding adjustment, the two outermost vertices are converted into a single vertex and the adjustment results in a periodic blending function mesh as shown at 910. When the blending function mesh is generated according to algorithms of the present disclosure, the algorithms can detect that there is a face with four vertices that needs to be created even though there are 5 vertices and can apply relevant adjustments to create the top quad face as shown at 910.

This demonstrates a case where welding is necessary. A blending function mesh can include one or more of their vertices that refer to overlapping locations on the original control mesh.

In some instances, the generation of the blending function mesh can include an identification (e.g., performed as a check during the processing) that the control mesh has a periodic representation including more vertices for faces on the mesh compared to the vertices on the T-spline surface. The generation of the further topology for the blending function mesh, as described in relation to operation 310 of FIG. 3A, or as described for FIG. 3B, can include an operation to determine periodicity in the control mesh and to guide the generation of the blending function mesh according to the determined periodicity. In such manner, matching (based on the welding) vertices and edges aligned with vertices and edges of the control mesh can be associated based on determining that the matching vertices and edges are associated with overlapping locations on the T-spline surface. When the blending function mesh is generation, the vertex 905 will be determined as engulfed by the blending function, and the blending function mesh will be modified to 910 to generate the 2-neighborhood around the central vertex as shown at 910.

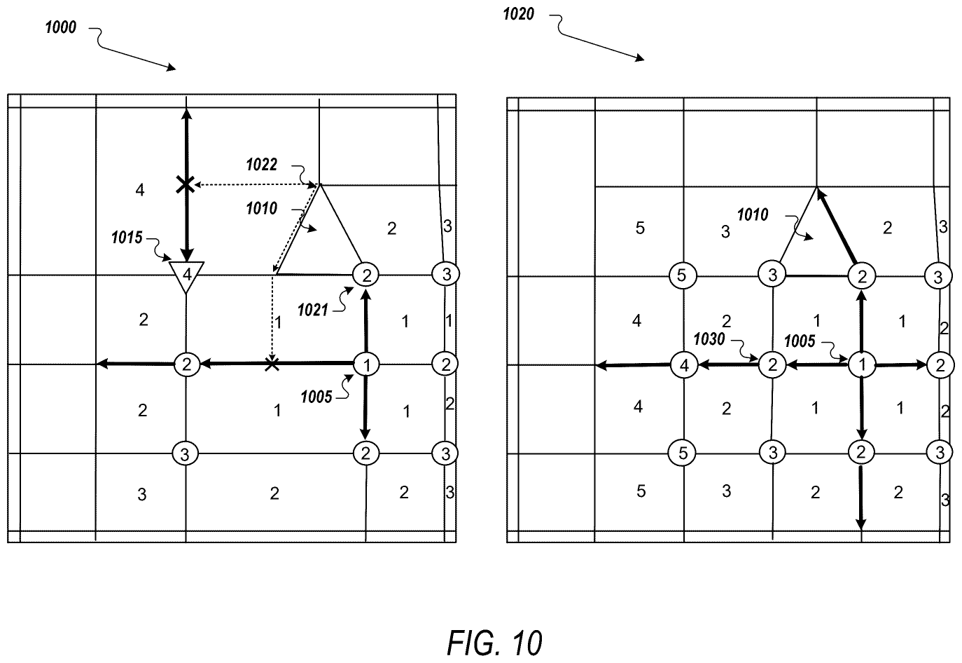

FIG. 10 shows a presentation 1000 of a control mesh that engulfs a hole 1010. When the control mesh includes a hole as shown on at 1000, a blending function mesh is generated starting with the central vertex of the control mesh that is associated with a central axial vertex 1005 at the blending function mesh, labeled as 1 to correspond to the order of processing. Subsequent vertices and edges are added to the topology, as described in the present disclosure.

For example, as shown at diagram 1020, during the generation of the subsequent rings of faces for the blending function mesh topology, the presence of the hole 1010 can interfere with the generation of further topology for the blending function mesh. As shown, when the blending function mesh topology is expanded to add more and more vertices and edges as shown at 1000, where at the second iteration, two vertices annotated with 2 are added, and then, at a third iteration, three vertices annotated with 3 are added, and at a fourth, iteration, the vertex 1015 is determined to be engulfed by the blending function mesh. In that case, a rewind and retry procedure, as previously discussed, can be invoked, and the blending function generation can be reverted back to the vertices and edged added at the second iteration (as the vertex 1021 is the vertex preceding the engulfed vertex 1015 is the previous vertex). Based on invoking the rewind and retry procedure, the blending function mesh can be generated as shown at 1020, where a ghost vertex 1030 is added to the topology of the blending function mesh, where the ghost vertex 1030 is determined as influenced from the top vertex 1022 of the hole (shown with the arrows at 1000).

In some instances, the generation of further topology for the blending function mesh as described in relation to operation 320 of FIG. 3A comprises generating rings of faces and when determining that a vertex on an edge of a hole identified in the control mesh is engulfed (that is the vertex 1022), a ghost vertex is determined to be introduced into the blending function mesh (i.e., vertex 1030 as shown on 1020). The ghost vertex aligns with the hole and extends a central edge (extending from central vertex 1005) that is already included in the topology of the blending function mesh.

The control mesh of the example of FIG. 10 includes extraordinary points (e.g., the top of the triangular hole 1010 that corresponds to the vertex 1022 of 1000) in the vicinity of T-junctions (vertex labeled with “3” on 1020). However, there can be cases where the control mesh engulfs a hole and the control mesh does not include extraordinary points. It should be noted that the corner of the hole (in this example an extraordinary point) does not have to be an extraordinary point but can require adjustments that are similar to the adjustments done for an engulfed extraordinary point.

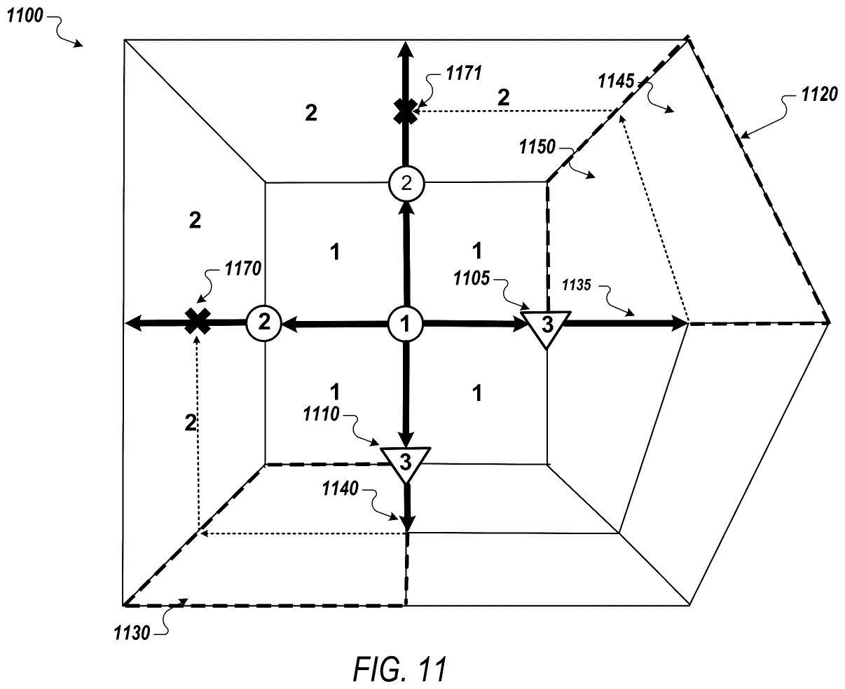

FIG. 11 shows a control mesh 1100 that is associated with detection of engulfment when generating the blending function mesh. In this example, the engulfment is detected when attempting to infer a face (i.e., presented in dashed lines and labeled as 1120, as well as the face 1130) where the knot intervals associated with the inferred face do not match. All faces in a blending function mesh should have matching knot intervals on opposite sides of the face. In the present example, the face 1120 will have a short knot interval on 1135 and a long knot interval on the opposite side. On face 1130, the short knot interval will appear on 1140 and the long knot interval on the opposite side. The engulfed vertex would be detected always at the tip of the shorter side.

In the present example, the shape of the face is an irregular quadrilateral (1120) or irregular trapezoid (1130). To handle the inference of a blending function based on generation of a blending function mesh, when the blending function mesh topology is determined, the tip of the shorter side, e.g., vertex 1105 or vertex 1110, can be treated as an engulfed vertex. When a rewind and retry procedure is invoked based on determining the engulfment, the blending function mesh can be reverted to a previous state including vertices determined for the 1-neighborhood of faces, and then, additional topology can be added (as part of the retry step) to include edges that do not extend to the longer axial edge of the face. For example, edges 1135 and 1140 can be determined to be added to form further faces, where the vertices at the end of the edges 1135 and 1140 do not extend to the end point of the respective faces 1120 and 1130. As such, faces 1150 and 1145 are defined within the face 1120 for the blending function mesh, and respective two faces are defined for the face 1130.

In the present example of FIG. 11, the location of the arrow-tip of edge 1135 and the location at the arrow-tip of edge 1140 are considered as engulfed locations. These engulfed locations in turn produce ghost vertices at the locations marked with X (1170 and 1171).

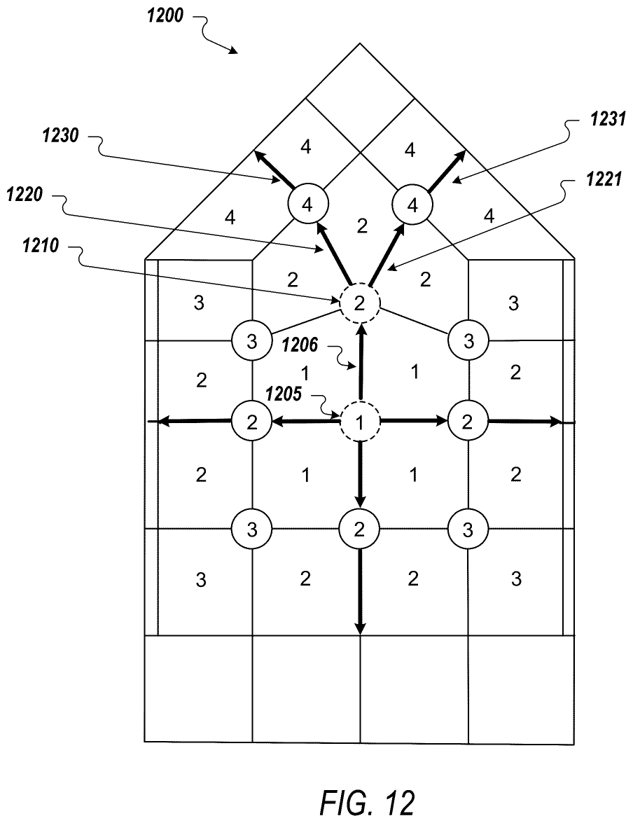

FIG. 12 shows an example 1200 for generating a blending function mesh based on a control mesh having an axial edge touching a center of an N-gon in the control mesh. The example 1200 shows consecutive steps annotated with respective numbers for generating a blending function mesh. The central vertex of the blending function is 1205 and an axial edge of the blending function mesh (i.e., edge 1206) touches a center of an n-gon (vertex 1210). In such case, the center of the N-gon (vertex 1210) can be treated as a ghost vertex for the generation of the blending function mesh during the rewind and retry procedure. When the knot insertion algorithm is executed, the knot insertion can be with consideration of the presence of extraordinary points along the axes. The knot insertion is executed since the vertex 1210 would be associated with a non-zero coefficient. Knot insertion requires a knot vector including several edge intervals (e.g., cubic knot insertion requires gathering four edge intervals). In some cases of example 1200 of FIG. 12, it may be ambiguous how the edge intervals are to be determined. In some instances, the ambiguity can be resolved by taking an arithmetic mean of edges at equivalent distances, such as taking the mean of edges 1220 and 1221 for the first edge interval, and the mean of the edges 1230 and 1231 for the second edge interval. In some examples, to resolve the ambiguity and define how to determine the edge internals include using a geometric mean, a maximum interval, or a minimum interval of the ambiguous edges, among other examples.

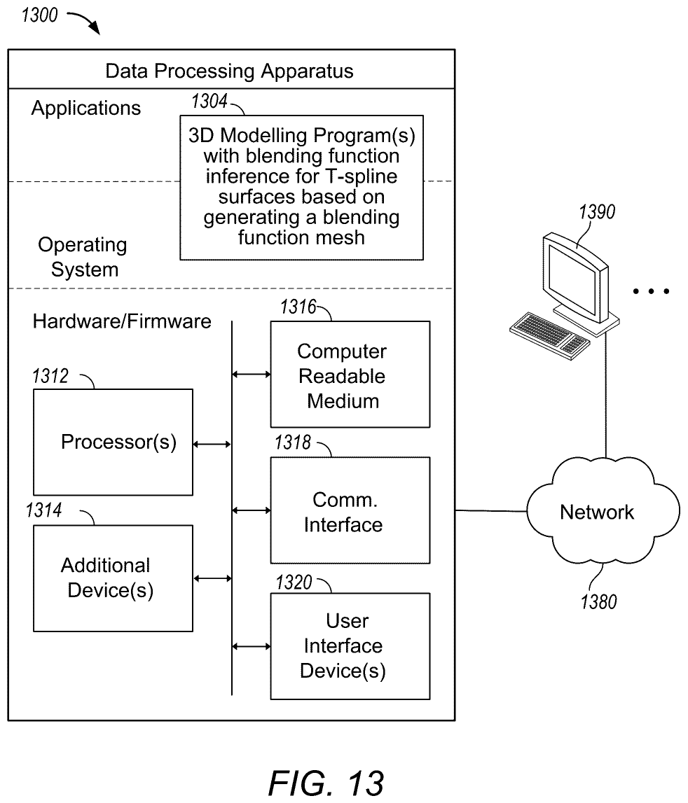

FIG. 13 is a schematic diagram of a data processing system including a data processing apparatus 1300, which can be programmed as a client or as a server. The data processing apparatus 1300 is connected with one or more computers 1390 through a network 1380. While only one computer is shown in FIG. 13 as the data processing apparatus 1300, multiple computers can be used. The data processing apparatus 1300 includes various software modules, which can be distributed between an applications layer and an operating system. These can include executable and/or interpretable software programs or libraries, including tools and services of one or more 3D modeling programs 1304 that implement the systems and techniques described herein. Thus, the 3D modeling program(s) 1304 can be CAD program(s) 1304 that implement 3D modeling functions and can include technique to produce a smooth surface based on generation of blending function meshes in accordance with techniques of the present disclosure. The 3D modeling program(s) 1204 can include logic for inferring a blending function for a T-spline surface based on generating a blending function mesh.

Further, the program(s) 1304 can implement physical simulation operations (finite element analysis (FEA) or other), generative design operations (e.g., using level-set based method(s) for generative design), manufacturing control operations (e.g., generating and/or applying toolpath specifications to effect manufacturing of designed objects), and/or movie animation production. The number of software modules used can vary from one implementation to another. Moreover, the software modules can be distributed on one or more data processing apparatus connected by one or more computer networks or other suitable communication networks.

The data processing apparatus 1300 also includes hardware or firmware devices including one or more processors 1312, one or more additional devices 1314, a computer readable medium 1316, a communication interface 1318, and one or more user interface devices 1320. Each processor 1312 is capable of processing instructions for execution within the data processing apparatus 1300. In some implementations, the processor 1312 is a single or multi-threaded processor. Each processor 1312 is capable of processing instructions stored on the computer readable medium 1316 or on a storage device such as one of the additional devices 1314. The data processing apparatus 1300 uses the communication interface 1318 to communicate with one or more computers 1390, for example, over the network 1380. Examples of user interface devices 1320 include a display, a camera, a speaker, a microphone, a tactile feedback device, a keyboard, a mouse, and VR and/or AR equipment. The data processing apparatus 1300 can store instructions that implement operations associated with the program(s) described above, for example, on the computer readable medium 1316 or one or more additional devices 1314, for example, one or more of a hard disk device, an optical disk device, a tape device, and a solid state memory device.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented using one or more modules of computer program instructions encoded on a non-transitory computer-readable medium for execution by, or to control the operation of, data processing apparatus. The computer-readable medium can be a manufactured product, such as hard drive in a computer system or an optical disc sold through retail channels, or an embedded system. The computer-readable medium can be acquired separately and later encoded with the one or more modules of computer program instructions, e.g., after delivery of the one or more modules of computer program instructions over a wired or wireless network. The computer-readable medium can be a machine-readable storage device, a machine-readable storage substrate, a memory device, or a combination of one or more of them.

The term “data processing apparatus” encompasses all apparatus, devices, and machines for processing data, including by way of example a programmable processor, a computer, or multiple processors or computers. The apparatus can include, in addition to hardware, code that produces an execution environment for the computer program in question, e.g., code that constitutes processor firmware, a protocol stack, a database management system, an operating system, a runtime environment, or a combination of one or more of them. In addition, the apparatus can employ various different computing model infrastructures, such as web services, distributed computing and grid computing infrastructures.

A computer program (also known as a program, software, software application, script, or code) can be written in any suitable form of programming language, including compiled or interpreted languages, declarative or procedural languages, and it can be deployed in any suitable form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., a field programmable gate array (FPGA) or an application-specific integrated circuit (ASIC).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM (Erasable Programmable Read-Only Memory), EEPROM (Electrically Erasable Programmable Read-Only Memory), and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a liquid crystal display (LCD) device, an organic light emitting diode (OLED) display device, or another monitor, for displaying information to the user, and a keyboard and a pointing device, e.g., a mouse or a trackball, by which the user can provide input to the computer. Other kinds of devices can be used to provide for interaction with a user as well; for example, feedback provided to the user can be any suitable form of sensory feedback, e.g., visual feedback, auditory feedback, or tactile feedback; and input from the user can be received in any suitable form, including acoustic, speech, or tactile input.

The computing system can include clients and servers. A client and server are generally remote from each other and typically interact through a communication network. The relationship of client and server arises by virtue of computer programs running on the respective computers and having a client-server relationship to each other. Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a browser user interface through which a user can interact with an implementation of the subject matter described is this specification, or any combination of one or more such back-end, middleware, or front-end components. The components of the system can be interconnected by any suitable form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While this specification contains many implementation details, these should not be construed as limitations on the scope of what is being or may be claimed, but rather as descriptions of features specific to particular embodiments of the disclosed subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the invention have been described. Other embodiments are within the scope of the following claims. In addition, actions recited in the claims can be performed in a different order and still achieve desirable results.

What is claimed is:

1. A computer-implemented method comprising:
obtaining a control mesh for a T-spline surface;
generating a blending function mesh for inferring a blending function for a control point of the T-spline surface by defining a topology for the blending function mesh, wherein defining the topology for the blending function mesh comprises
defining a central vertex and central edges of the blending function mesh that are inferred from the control mesh, and
generating further topology for the blending function mesh by directly inferring further faces and edges for the blending function mesh from the defined central edges of the blending function mesh;
inferring the blending function for the T-spline surface from the generated blending function mesh; and
providing the inferred blending function for use for computing the T-spline surface.

2. The method of claim 1, wherein the control mesh includes a T-junction that falls within a two-ring of faces around an extraordinary point.

3. The method of claim 1, comprising:
computing, based on the inferred blending function, the T-spline surface for rendering on a user interface; and
rendering the T-spline surface on the user interface of a display of a device.

4. The method of claim 1, wherein the further topology includes one or more axial edges into the blending function mesh that are measured based on the control mesh to be included in the blending function mesh.

5. The method of claim 1, wherein generating the further topology for the blending function mesh comprises:
generating a ghost edge and/or a ghost vertex to be included in the blending function mesh to align an extraordinary point in the blending function mesh with continuity breaks of the blending function, wherein the extraordinary point in the blending function is inferred from an extraordinary point at the control mesh, wherein the blending function mesh that includes the ghost edge and ghost vertex does not include T-junctions.

6. The method of claim 5, wherein the ghost edge and/or the ghost vertex has a knot multiplicity of zero when added as part of the further topology of the blending function mesh.

7. The method of claim 5, wherein inferring the blending function from the generated blending function mesh comprises:
executing knot insertion for the ghost edge to build knot vectors for the blending function that include non-zero coefficients for ghost vertices in the blending function mesh.

8. The method of claim 1, wherein generating the further topology for the blending function mesh comprises:
incrementally adding rings of faces as part of the further topology of the blending function mesh;
labeling each incrementally added face of the blending function mesh with a value corresponding to a ring of faces with which the respective face is associated; and
determining to add an additional ring of faces to the blending function mesh when a face on an exterior of a current state of generation of the blending function mesh is labeled with a value that is less than a value corresponding to a current incrementally added ring of faces.

9. A system comprising:
a non-transitory storage medium having instructions of a computer aided design program stored thereon; and
one or more data processing apparatus able to run the instructions of the computer aided design program to perform operations comprising:
obtaining a control mesh for a T-spline surface;
generating a blending function mesh for inferring a blending function for a control point of the T-spline surface by defining a topology for the blending function mesh, wherein defining the topology for the blending function mesh comprises
defining a central vertex and central edges of the blending function mesh that are inferred from the control mesh, and
generating further topology for the blending function mesh by directly inferring further faces and edges for the blending function mesh from the defined central edges of the blending function mesh;
inferring the blending function for the T-spline surface from the generated blending function mesh; and
providing the inferred blending function for use for computing the T-spline surface.

10. The system of claim 9, wherein the control mesh includes a T-junction that falls within a two-ring of faces around an extraordinary point.

11. The system of claim 9, wherein the operations comprise:
computing, based on the inferred blending function, the T-spline surface for rendering on a user interface; and
rendering the T-spline surface on the user interface of a display of a device.

12. The system of claim 9, wherein the further topology includes one or more axial edges into the blending function mesh that are measured based on the control mesh to be included in the blending function mesh.

13. The system of claim 9, wherein generating the further topology for the blending function mesh comprises:
generating a ghost edge and/or a ghost vertex to be included in the blending function mesh to align an extraordinary point in the blending function mesh with continuity breaks of the blending function, wherein the extraordinary point in the blending function is inferred from an extraordinary point at the control mesh, wherein the blending function mesh that includes the ghost edge and ghost vertex does not include T-junctions.

14. The system of claim 13, wherein the ghost edge and/or the ghost vertex has a knot multiplicity of zero when added as part of the further topology of the blending function mesh.

15. The system of claim 13, wherein inferring the blending function from the generated blending function mesh comprises:
executing knot insertion for the ghost edge to build knot vectors for the blending function that include non-zero coefficients for ghost vertices in the blending function mesh.

16. The system of claim 9, wherein generating the further topology for the blending function mesh comprises:
incrementally adding rings of faces as part of the further topology of the blending function mesh;
labeling each incrementally added face of the blending function mesh with a value corresponding to a ring of faces with which the respective face is associated; and
determining to add an additional ring of faces to the blending function mesh when a face on an exterior of a current state of generation of the blending function mesh is labeled with a value that is less than a value corresponding to a current incrementally added ring of faces.

17. A non-transitory computer-readable medium encoding instructions operable to cause data processing apparatus to perform operations comprising:
obtaining a control mesh for a T-spline surface;
generating a blending function mesh for inferring a blending function for a control point of the T-spline surface by defining a topology for the blending function mesh, wherein defining the topology for the blending function mesh comprises
defining a central vertex and central edges of the blending function mesh that are inferred from the control mesh, and
generating further topology for the blending function mesh by directly inferring further faces and edges for the blending function mesh from the defined central edges of the blending function mesh;
inferring the blending function for the T-spline surface from the generated blending function mesh; and
providing the inferred blending function for use for computing the T-spline surface.

18. The non-transitory computer-readable medium of claim 17, wherein the control mesh includes a T-junction that falls within a two-ring of faces around an extraordinary point.

19. The non-transitory computer-readable medium of claim 17, encoding further instructions operable to cause the data processing apparatus to perform operations comprising:
computing, based on the inferred blending function, the T-spline surface for rendering on a user interface; and
rendering the T-spline surface on the user interface of a display of a device.

20. The non-transitory computer-readable medium of claim 17, wherein generating the further topology for the blending function mesh comprises:
generating a ghost edge and/or a ghost vertex to be included in the blending function mesh to align an extraordinary point in the blending function mesh with continuity breaks of the blending function, wherein the extraordinary point in the blending function is inferred from an extraordinary point at the control mesh, wherein the blending function mesh that includes the ghost edge and ghost vertex does not include T-junctions.
